(19) United States
(12) Patent Application Publication
(10) Pub. No.: US 2017/0040233 A1
(43) Pub. Date: Feb. 9, 2017

(54) Substrate Processing Apparatus and Substrate Processing System

(71) Applicant: Hitachi Kokusai Electric Inc., Tokyo (JP)

(72) Inventors: Naofumi OHASHI, Toyama (JP); Satoshi TAKANO, Toyama (JP); Toshiyuki KIKUCHI, Toyama (JP)

(21) Appl. No.: 15/252,400

(22) Filed: Aug. 31, 2016

Related U.S. Application Data
(63) Continuation-in-part of application No. 14/858,550, filed on Sep. 18, 2015, now abandoned.

(30) Foreign Application Priority Data
Aug. 4, 2015 (JP) 2015-154394

(51) Int. Cl. H01L 21/66; H01L 21/321; B24B 37/10; H01L 21/67; H01L 29/66; H01L 21/28; H01L 21/3213

(52) U.S. Cl. CPC H01L 22/20; H01L 21/28035; H01L 21/3212; H01L 21/32139; H01L 21/67253; H01L 29/66795; B24B 37/107

(57) ABSTRACT

Deviation in properties of a semiconductor is suppressed. Provided is a configuration including a receiving member configured to receive data representing a film thickness distribution of a silicon-containing film formed on a substrate, a substrate support where the substrate is placed, a gas supply member configured to supply gases in a manner that a hard mask film having a film thickness distribution different from that of the silicon-containing film is formed on the silicon-containing film to maintain a height of an upper surface of the hard mask film in a predetermined range.

### CROSS REFERENCE TO RELATED APPLICATIONS

This application is a continuation-in-part of non-provisional U.S. patent application Ser. No. 14/858,550 filed Sep. 18, 2015, and claims priority under 35 U.S.C. §119 of Japanese Patent Application No. 2015-154394, filed on Aug. 4, 2015, in the Japanese Patent Office, the entire contents of which are hereby incorporated by reference.

### FIELD OF THE INVENTION

The present invention relates to a substrate processing apparatus, a substrate processing system, a method of manufacturing a semiconductor device and a recording medium.

### BACKGROUND

In recent times, a semiconductor device tends to be highly integrated. Accordingly, a size of a pattern is remarkably reduced. Such pattern is formed through a forming process, a lithography process, an etching process, and so on, of a hard mask film or a resist film. The pattern should be formed not to generate deviation of properties of the semiconductor device.

As a method of forming a pattern, for example, a method disclosed in Japanese Unexamined Patent Application, First Publication No. 2013-26399 is provided.

Meanwhile, deviation may occur from a width of a circuit or the like due to problems on machining. In particular, in the miniaturized semiconductor device, the deviation exerts a large influence on the properties of the semiconductor device.

### SUMMARY

Accordingly, the present invention is directed to provide a technology capable of suppressing deviation of properties of a semiconductor device.

According to an aspect of the present invention, there is provided a configuration including a receiving member configured to receive data representing a film thickness distribution of a silicon-containing film formed on a substrate, a substrate support where the substrate is placed, a gas supply member configured to supply gases in a manner that a hard mask film having a film thickness distribution different from that of the silicon-containing film is formed on the silicon-containing film to maintain a height of an upper surface of the hard mask film in a predetermined range.

### BRIEF DESCRIPTION OF THE DRAWINGS

FIG. 1 is a view for describing a manufacturing flow of a semiconductor device according to an embodiment of the present invention.

FIGS. 2A and 2B are views for describing a wafer according to the embodiment.

FIGS. 3A, 3B and 3C are views for describing a wafer according to the embodiment.

FIG. 4 is a view for describing a polishing apparatus according to the embodiment.

FIG. 5 is a view for describing the polishing apparatus according to the embodiment.

FIG. 6 is a view for describing film thickness distribution of a poly-Si film according to the embodiment.

FIGS. 7A and 7B are views for describing a processing state of a wafer according to the embodiment.

FIG. 8 is a view for describing film thickness distribution of the poly-Si film according to the embodiment.

FIGS. 9A and 9B are views for describing a processing state of the wafer according to the embodiment.

FIG. 10 is a view for describing film thickness distribution of the poly-Si film according to the embodiment.

FIG. 11 is a view for describing a substrate processing apparatus according to the embodiment.

FIG. 12 is a view for describing a shower head of the substrate processing apparatus according to the embodiment.

FIG. 13 is a view for describing a gas supply system of the substrate processing apparatus according to the embodiment.

FIG. 14 is a view for describing the gas supply system of the substrate processing apparatus according to the embodiment.

FIG. 15 is a schematic configuration view of a controller according to the embodiment.

FIGS. 16A and 16B are views for describing a processing state of a wafer according to the embodiment.

FIGS. 17A and 17B are views for describing a processing state of a wafer according to the embodiment.

FIGS. 18A and 18B are views for describing a processing state of a wafer according to a comparative example.

FIGS. 19A and 19B are views for describing a processing state of a wafer according to the comparative example.

FIGS. 20A and 20B are views for describing a processing state of a wafer according to the comparative example.

FIG. 21 is a view for describing a system according to the embodiment.

FIG. 22 is a flowchart exemplifying a hard mask film forming process according to an embodiment of the present invention.

FIGS. 23A and 23B are tables for describing an adjustment of a film thickness of a hard mask film according to the embodiment of the present invention.

### DETAILED DESCRIPTION

Hereinafter, an embodiment of the present invention will be described with reference to the accompanying drawings.

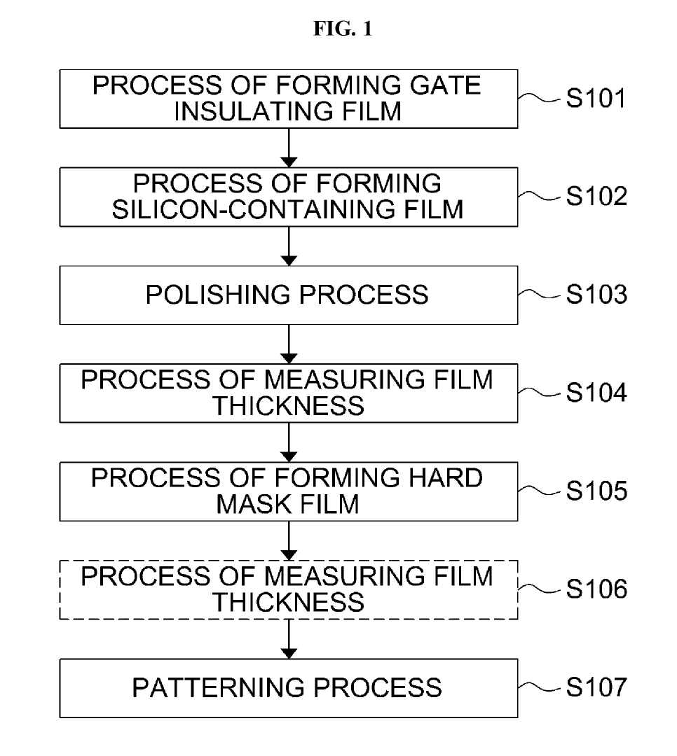

First, one of processes of manufacturing a semiconductor device will be exemplarily described using a fin field effect transistor (FinFET), which is one of semiconductor devices, with reference to FIGS. 1 through 3C.

### Summary of Manufacture of FinFET

The FinFET includes a convex structure (a Fin structure) formed on a wafer substrate (hereinafter, simply referred to as “a wafer”), which is referred to as, for example, a 300 mm wafer, and as shown in FIG. 1, is manufactured by sequentially performing a gate insulating film forming process (S101), a silicon-containing film forming process (S102), a polishing process (S103), a film thickness measurement process (S104) and a hard mask film forming process (S105), and, if necessary, a film thickness measurement process (S106) and a patterning process (S107). Hereinafter, these processes (S101) to (S107) will be described.

### Gate Insulating Film Forming Process (S101)

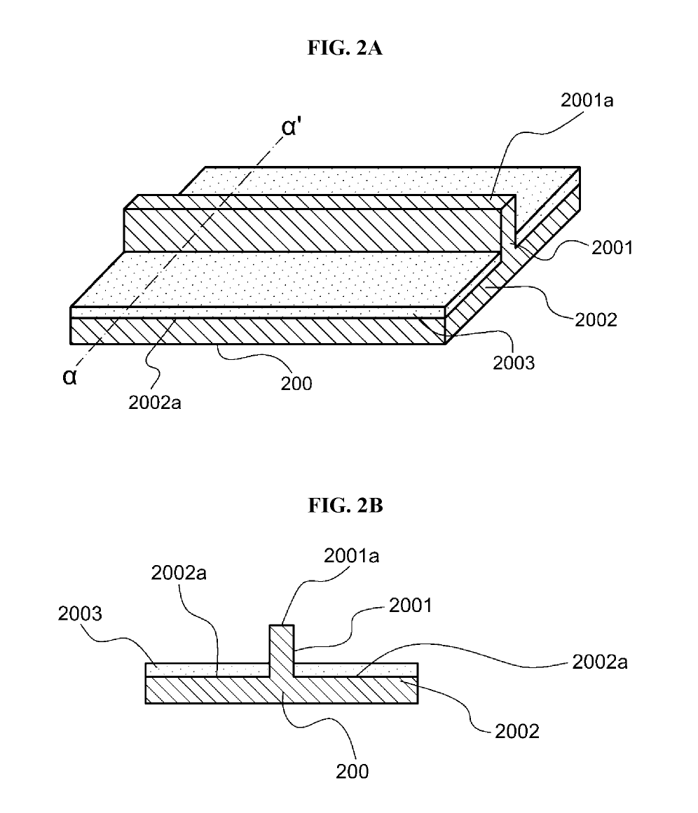

In the gate insulating film forming process (S101), for example, a wafer 200 having a structure shown in FIGS. 2A and 2B is loaded into a gate insulating film forming apparatus. FIG. 2A is a perspective view showing a portion of a structure formed on the wafer 200, and FIG. 2B shows a cross-sectional view taken along line α-α′ of FIG. 2A. The wafer 200 is formed of silicon or the like, and a convex structure 2001 serving as a channel is formed at a portion thereof. A plurality of convex structures 2001 are installed at predetermined intervals. The convex structures 2001 are formed by etching the portion of the wafer 200.

For the convenience of description, a portion on the wafer 200 having no convex structure 2001 is referred to as a concave structure 2002. That is, the wafer 200 includes at least the convex structure 2001 and the concave structure 2002. In addition, for the convenience of description of the embodiment, an upper surface of the convex structure 2001 is referred to as a convex structure surface 2001a, and an upper surface of the concave structure 2002 is referred to as a concave structure surface 2002a.

A device isolation film 2003 configured to electrically insulate the convex structure 2001 is formed on the concave structure surface 2002a between the neighboring convex structures 2001. The device isolation film 2003 is formed of, for example, a silicon oxide film.

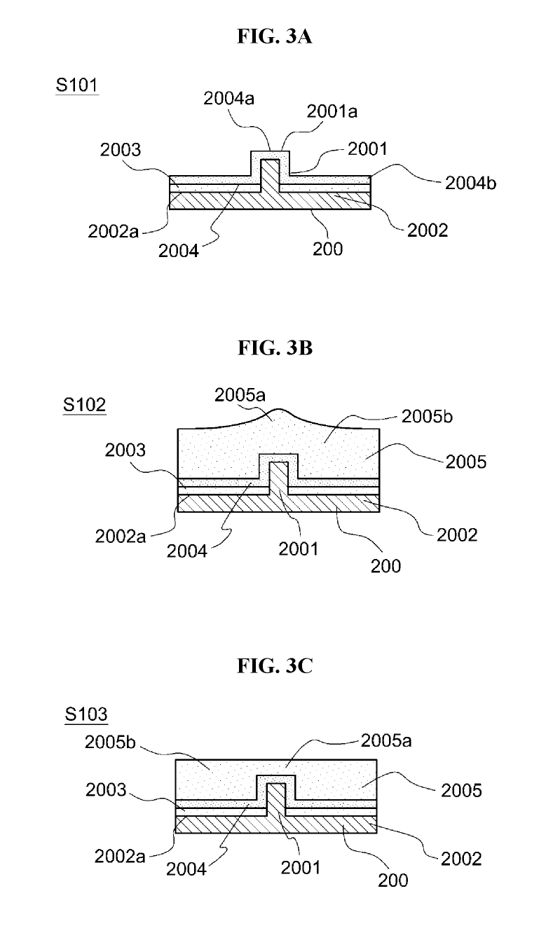

Since the gate insulating film forming apparatus is a known sheet feed apparatus capable of forming a thin film, description thereof will be omitted. In the gate insulating film forming apparatus, as shown in FIG. 3A, for example, a gate insulating film 2004 formed of a dielectric material such as a silicon oxide film (a SiO₂ film) or the like is formed. As a silicon-containing gas [for example, HCDS (hexachlorodisilane) gas] and an oxygen-containing gas (for example, O₃ gas) are supplied into the gate insulating film forming apparatus and react with each other, the gate insulating film 2004 is formed. The gate insulating film 2004 is formed on the convex structure surface 2001a and the concave structure surface 2002a. After the gate insulating film is formed, the wafer 200 is unloaded from the gate insulating film forming apparatus.

### Silicon-Containing Film Forming Process (S102)

Next, the silicon-containing film forming process (S102) will be described. After the wafer 200 is unloaded from the gate insulating film forming apparatus, the wafer 200 is loaded into the silicon-containing film forming apparatus. Since a general sheet-feeding CVD apparatus is used as the silicon-containing film forming apparatus, description thereof will be omitted. As shown in FIG. 3B, in the silicon-containing film forming apparatus, a poly-Si film 2005 (referred to as a silicon-containing layer or a silicon-containing film) formed of poly-Si (polycrystal silicon) is formed on the gate insulating film 2004. As disilane (Si₂H₆) gas is supplied into the silicon-containing film forming apparatus to be pyrolyzed, the poly-Si film 2005 is formed. The poly-Si film 2005 is used as a gate electrode or a dummy gate electrode. Since the desired poly-Si film 2005 is formed through one process, a film having a constant composition may be formed from a surface of the gate insulating film 2004 to a surface of the poly-Si film 2005. Accordingly, when the poly-Si film 2005 is used as a dummy gate, an etching volume per unit time on the substrate may be constant. In addition, when the poly-Si film 2005 is used as a gate electrode or the like, performance of the gate electrode may be constant.

After the poly-Si film 2005 is formed, the wafer 200 is unloaded from the silicon-containing film forming apparatus. In addition, a film accumulated on the convex structure surface 2001a is referred to as the poly-Si film 2005a, and a film formed on the concave structure surface 2002a is referred to as the poly-Si film 2005b.

### Polishing Process (S103)

Next, the polishing (chemical mechanical polishing (CMP)) process (S103) will be described. The wafer 200 unloaded from the silicon-containing film forming apparatus is loaded into a polishing apparatus (a CMP apparatus) 400.

Here, a poly-Si film formed in the silicon-containing film forming process (S102) will be described. As shown in FIG. 3B, since the convex structure 2001 and the concave structure 2002 are present on the wafer 200, a height of the poly-Si film 2005 is varied on a surface of the substrate. Specifically, a height from the concave structure surface 2002a to the surface of the poly-Si film 2005a on the convex structure 2001 is larger than a height from the concave structure surface 2002a to the surface of the poly-Si film 2005b on the concave structure surface 2002a.

However, due to a relation with respect to at least one of an exposure process and an etching process, which are to be described below, the height of the surface of the poly-Si film 2005a should be matched to the height of the surface of the poly-Si film 2005b. Accordingly, the height is adjusted by polishing the poly-Si film 2005 through the process.

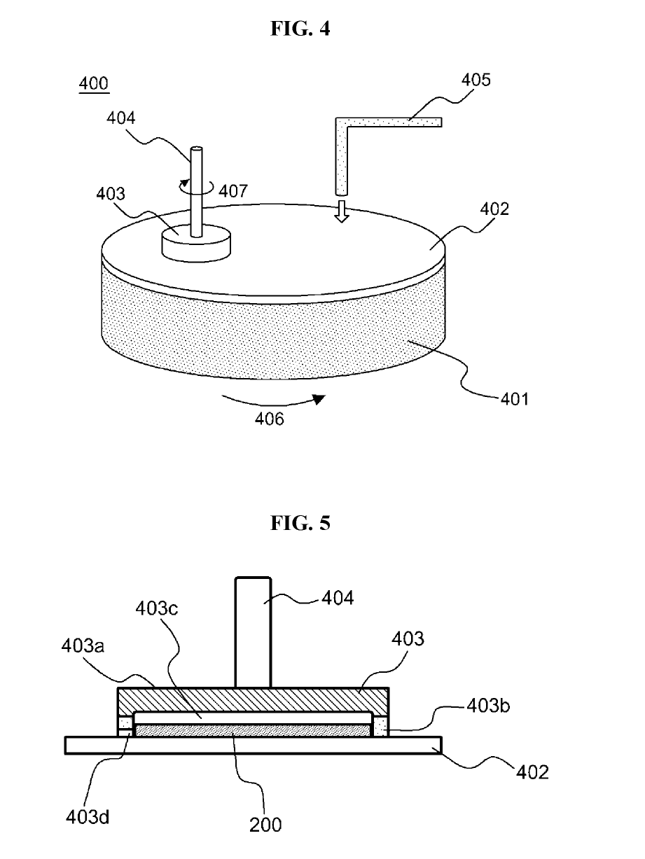

Hereinafter, the polishing process (S103) will be described in detail. After the wafer 200 is unloaded from the silicon-containing film forming apparatus, the wafer 200 is loaded into the polishing apparatus 400 shown in FIG. 4.

In FIG. 4, reference numeral 401 designates a polishing machine, and reference numeral 402 designates a polishing cloth configured to polish the wafer 200. The polishing machine 401 is connected to a rotary mechanism which is not shown and rotated in a direction of an arrow 406 when the wafer 200 is polished.

Reference numeral 403 is a polishing head, and a shaft 404 is connected to an upper surface of the polishing head 403. The shaft 404 is connected to a rotary mechanism/a vertical driving mechanism (not shown). The shaft is rotated in a direction of an arrow 407 while the wafer 200 is polished.

Reference numeral 405 designates a supply pipe configured to supply slurry (a polishing agent). The slurry is supplied from the supply pipe 405 toward the polishing cloth 402 while the wafer 200 is polished.

Next, the polishing head 403 and a peripheral structure thereof will be described with reference to FIG. 5. FIG. 5 is a view for describing the peripheral structure focusing on a cross-sectional view of the polishing head 403. The polishing head 403 includes a top ring 403a, a retainer ring 403b and an elastic mat 403c. An outer side of the wafer 200 is surrounded by the retainer ring 403b during the polishing, and pressed against the polishing cloth 402 by the elastic mat 403c. A groove 403d through which the slurry passes from the outside to the inside of the retainer ring 403b is formed in the retainer ring 403b. A plurality of grooves 403d are formed in a cylindrical shape to conform to a shape of the retainer ring 403b. New slurry is substituted with the used slurry via the groove 403d.

Next, a processing operation of the CMP apparatus in the process will be described. When the wafer 200 is loaded into the polishing head 403, the polishing machine 401 and the polishing head 403 are rotated while the slurry is supplied through the supply pipe 405. The slurry is introduced into the retainer ring 403b to polish the surface of the wafer 200. As shown in FIG. 3C, the heights of the surfaces of the poly-Si film 2005a and the poly-Si film 2005b are matched by the polishing as described above. “The heights of the surfaces” are referred to as the heights of the surfaces (upper surfaces) of the poly-Si film 2005a and the poly-Si film 2005b. When the polishing is performed for a predetermined time, the wafer 200 is unloaded from the polishing apparatus 400.

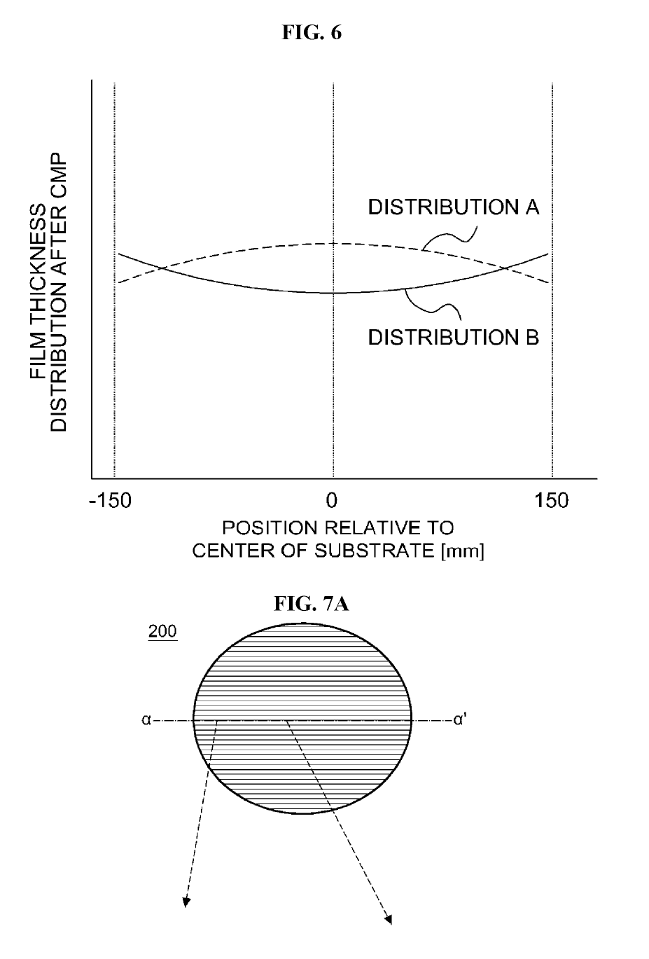

Meanwhile, even when the polishing is performed by the CMP apparatus 400 to match the heights of the surfaces of the poly-Si film 2005a and the poly-Si film 2005b, as shown in FIG. 6, the height of the surface (the film thickness) of the poly-Si film 2005 may not be matched after the polishing on the wafer 200. For example, film thickness distribution (distribution A in the drawing) in which a film thickness of an outer peripheral portion of the surface of the wafer 200 is smaller than a center portion or film thickness distribution (distribution B of the drawing) in which the film thickness of the center portion of the wafer 200 is smaller than that of the outer peripheral portion of the surface of the substrate may be found.

Deviation of the film thickness distribution causes generation of deviation in a width of a pattern in the patterning process (S107), which will be described below. In addition, deviation in a width of the gate electrode occurs due to the deviation of the film thickness distribution, and as a result, a yield may be decreased.

In this regard, as a result of research performed by the inventor(s) of the application, it was found that causes of the distribution A and the distribution B are different. Hereinafter, the causes will be described.

The cause of the distribution A is a method of supplying the slurry onto the wafer 200. As described above, the slurry supplied onto the polishing cloth 402 is supplied through the periphery of the wafer 200 via the retainer ring 403b. For this reason, while the slurry after the polishing of the outer peripheral portion of the surface of the wafer 200 is introduced at the center portion of the wafer 200, unused slurry is introduced into the outer peripheral portion of the surface of the wafer 200. The unused slurry has high polishing efficiency, and the outer peripheral portion of the surface of the wafer 200 is further polished than the center portion. From above, it was known that the film thickness of the poly-Si film 2005 is similar to the distribution A.

The cause of the distribution B is the wearing of the retainer ring 403b. When a large number of wafers 200 are polished by the polishing apparatus 400, a front end of the retainer ring 403b pressed against the polishing cloth 402 may be worn to deform a contact surface with the groove 403d or the polishing cloth 402. Accordingly, the slurry that is to be inherently supplied may not be supplied to an inner circumference of the retainer ring 403b. Since the slurry is not supplied to the outer peripheral portion of the surface of the wafer 200, the center portion of the wafer 200 is polished and the outer peripheral portion of the surface of the substrate is not polished. Accordingly, it was known that the film thickness of the poly-Si film 2005 is similar to the distribution B.

While the film thickness distribution like the distribution A or the distribution B is generated due to a structure of the CMP apparatus as described above, the structure of the CMP apparatus cannot be easily varied. Accordingly, in the embodiment, the deviation of the film thickness distribution of the poly-Si film 2005 is corrected by performing the film thickness measurement process (S104) and the hard mask film forming process (S105) on the poly-Si film 2005 after the polishing is performed in the polishing process (S103).

### Film Thickness Measurement Process (S104)

In the film thickness measurement process (S104), the film thickness of the poly-Si film 2005 polished through the polishing process (S103) is measured, and data related to the film thickness distribution (hereinafter, simply referred to as “film thickness distribution data”) of the poly-Si film 2005 on the surface of the substrate are acquired from the measurement result.

Measurement of the film thickness is performed using the film thickness measurement apparatus. That is, upon the film thickness measurement of the poly-Si film 2005, the wafer 200 unloaded from the CMP apparatus is loaded into the film thickness measurement apparatus. The “film thickness” disclosed herein is, for example, the height from the concave structure surface 2002a to the surface of the poly-Si film 2005. In addition, the film thickness measurement apparatus may have a general configuration regardless of an optical type or a contact type, and detailed description thereof will be omitted.

When the wafer 200 after performing the polishing process (S103) is loaded into the film thickness measurement apparatus, a plurality of film thicknesses (heights) including at least a central side and an outer circumferential side of the wafer 200 with respect to the poly-Si film 2005 on the wafer 200 are measured, and thus, the film thickness distribution data of the poly-Si film 2005 on the surface of the wafer 200 are obtained. It can be known whether the film thickness distribution after performing the polishing process (S103) with respect to the poly-Si film 2005 is the distribution A or the distribution B as the measurement is performed. In addition, when the film thickness distribution data are obtained through the measurement, the wafer 200 is unloaded from the film thickness measurement apparatus.

The film thickness distribution data obtained through the film thickness measurement apparatus are sent to an upstream apparatus of at least the film thickness measurement apparatus. In addition, the data may be sent to the substrate processing apparatus configured to perform the hard mask film forming process (S105), which will be described below, via the upstream apparatus. Accordingly, the upstream apparatus (including also the substrate processing apparatus when the data are sent to the substrate processing apparatus) can acquire the film thickness distribution data from the film thickness measurement apparatus.

### Hard Mask Film Forming Process (S105)

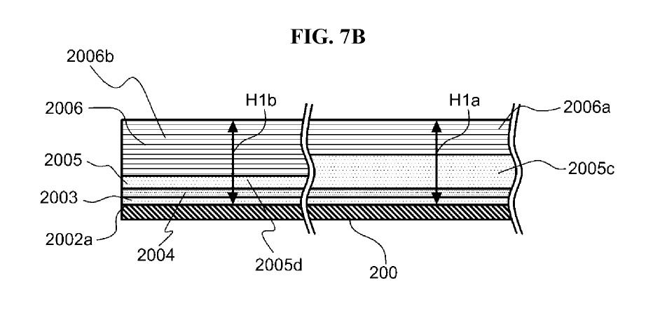

Next, the hard mask film forming process (S105) will be described. A hard mask film 2006 formed in the process is formed of a compound different from the poly-Si film 2005. As shown in FIGS. 7A and 7B, the hard mask film 2006 is formed on the poly-Si film 2005 after the polishing. The hard mask film 2006 is a film stronger than the poly-Si film 2005, and used as a hard mask film, for example, an etching stopper film, a polishing stopper film, or the like. When a damascene wiring is formed, the hard mask film 2006 may be used as a barrier insulating film. The hard mask film 2006 may use, for example, a silicon oxide film or a silicon carbide film instead of the silicon nitride film.

The hard mask film 2006 (simply referred to as a SiN film or a correcting film) is formed to correct the film thickness distribution of the poly-Si film 2005 after the polishing. More preferably, the hard mask film 2006 is formed such that the height of the surface of the hard mask film 2006 is matched on the surface of the wafer 200. The “height” disclosed herein is referred to as the height of the surface (the upper surface) of the hard mask film 2006, and in other words, referred to as a distance from the concave structure surface 2002a to the surface (the upper surface) of the hard mask film 2006.

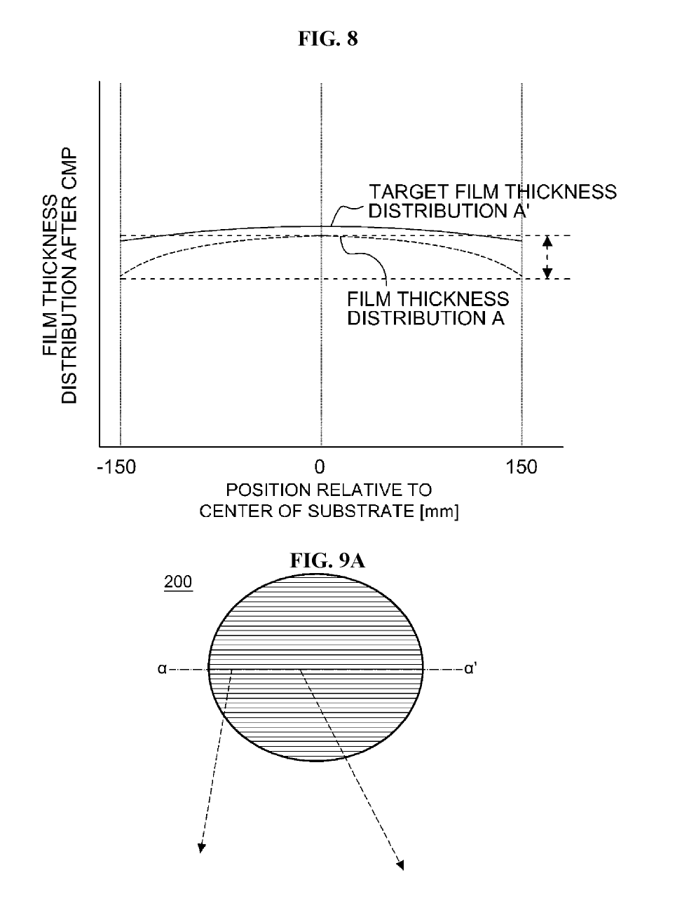

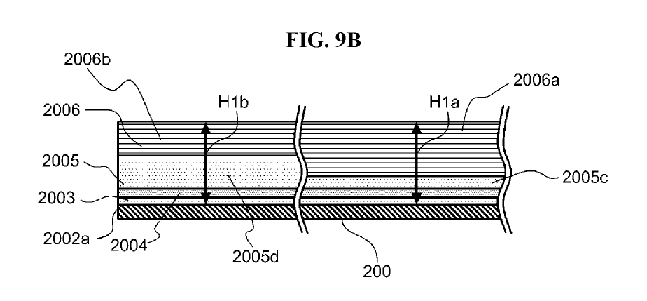

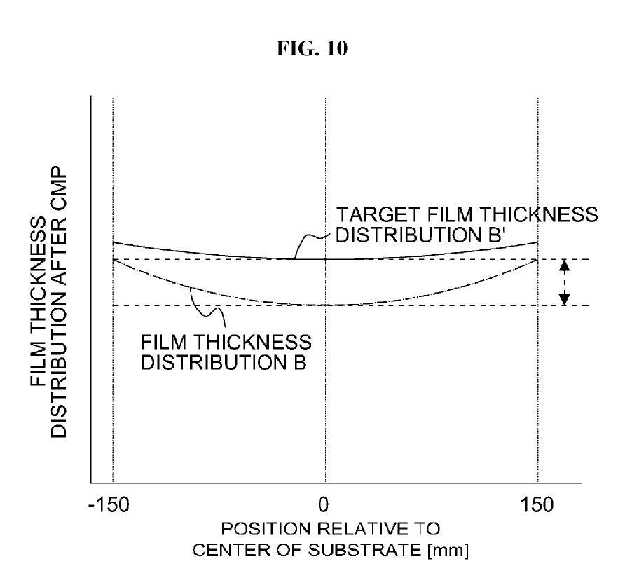

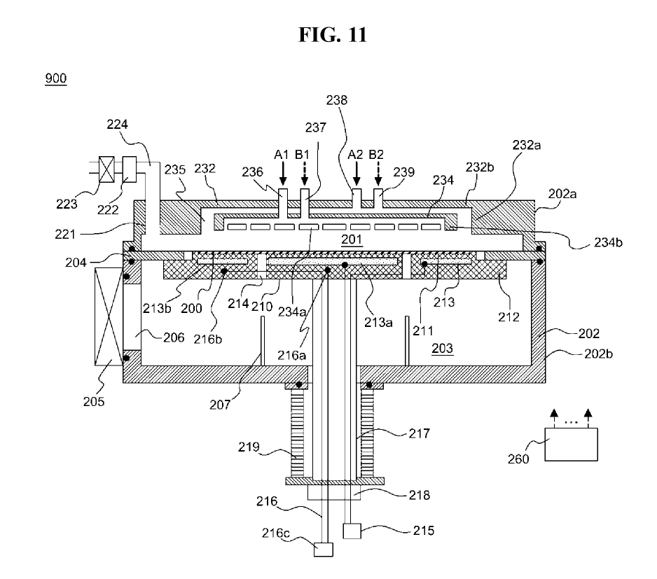

Hereinafter, the process will be described with reference to FIGS. 7A through 15. FIGS. 7A and 7B are views for describing the hard mask film 2006 formed in the process when the poly-Si film 2005 becomes the distribution A. FIG. 8 is a view for describing the film thickness distribution A and the film thickness distribution A′ after the correction. FIGS. 9A and 9B are views for describing the hard mask film 2006 formed in the process when the poly-Si film 2005 becomes the distribution B. FIG. 10 is a view for describing the film thickness distribution B and the film thickness distribution B′ after the correction. FIGS. 11 through 15 are views for describing the substrate processing apparatus configured to realize the process.

FIG. 7A is a view showing the wafer 200 when seen from above after the hard mask film 2006 is formed, and FIG. 7B is a cross-sectional view taken along line α-α′ of FIG. 7A, showing the center and the periphery of the wafer 200 extracted therefrom.

FIG. 9A is a view of the wafer 200 when seen from above when the hard mask film 2006 is formed, and FIG. 9B is a cross-sectional view taken along line α-α′ of FIG. 9A, showing the center and the periphery of the wafer 200.

Here, the hard mask film at the center portion of the wafer 200 is referred to as the hard mask film 2006a, and the hard mask film at the outer peripheral portion of the surface of the substrate is referred to as the hard mask film 2006b.

The wafer 200 unloaded from the measurement instrument is loaded into a substrate processing apparatus 900 serving as a hard mask film forming apparatus shown in FIG. 11.

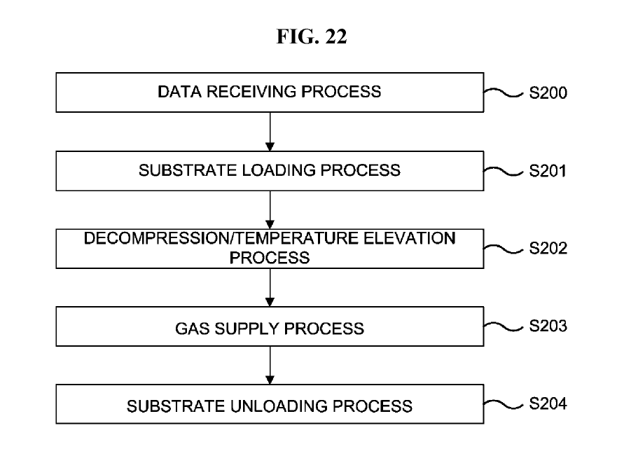

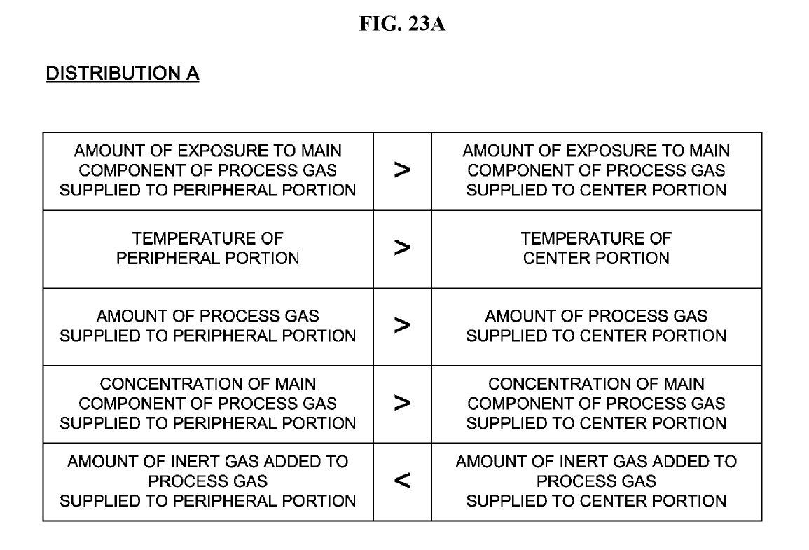

The substrate processing apparatus 900 controls the film thickness of the hard mask film 2006 on the surface of the substrate based on the data measured in the film thickness measurement process (S104). For example, when the data received from the upstream apparatus in a data receiving process S200 shown in FIG. 22 indicates the distribution A, as shown in FIG. 7B, the hard mask film 2006b of the outer peripheral portion of the surface of the wafer 200 is thickened, and the film thickness is controlled such that the hard mask film 2006a at the center portion is thinner than the hard mask film 2006b. In addition, when the data received from the upstream apparatus in the data receiving process S200 shown in FIG. 22 indicates the distribution B, as shown in FIG. 9B, the hard mask film 2006a at the center portion of the wafer 200 is thickened, and the film thickness is controlled such that the hard mask film 2006b of the outer peripheral portion of the surface of the substrate is thinner than the hard mask film 2006a.

More preferably, the thickness of the hard mask film 2006 is controlled such that the height of the deposition film formed by overlapping the poly-Si film 2005 and the hard mask film 2006, i.e., the hard mask film formed on the poly-Si film is within a predetermined range on the surface of the wafer 200 when seen from the concave structure surface 2002a. In other words, the film thickness distribution of the hard mask film is controlled such that the height of the surface of the hard mask film 2006 is formed within a predetermined range on the surface of the substrate. Accordingly, as shown in FIGS. 7B and 9B, a height H1a from the concave structure surface 2002a at the center portion of the wafer 200 to the upper end of the hard mask film 2006a can be matched to a height H1b from the concave structure surface 2002a at the outer peripheral portion of the surface of the wafer 200 to the upper end of the hard mask film 2006b.

Next, the substrate processing apparatus 900 capable of controlling the film thicknesses of the hard mask film 2006a and the hard mask film 2006b will be described in detail.

The processing apparatus 900 according to the embodiment will be described. As shown in FIG. 11, the substrate processing apparatus 900 is configured as a sheet-feed (single wafer?) type substrate processing apparatus.

The substrate processing apparatus 900 includes a processing container 202. For example, the processing container 202 is formed in a circular transverse cross section and configured in a flat sealing container. In addition, the processing container 202 is formed of a metal material such as aluminum (Al) or stainless steel (SUS), or quartz. A processing space 201 (a processing chamber) configured to process the wafer 200 such as a silicon wafer or the like serving as a substrate, and a conveyance space 203 are formed in the processing container 202. The processing container 202 is constituted by an upper container 202a and a lower container 202b. A partition plate 204 is installed between the upper container 202a and the lower container 202b. A space surrounded by the upper container 202a and disposed over the partition plate 204 is referred to as the processing space 201 (also referred to as a processing chamber), and a space surrounded by the lower container 202b and disposed under the partition plate 204 is referred to as the conveyance space 203.

A substrate loading/unloading port 206 adjacent to a gate valve 205 is installed at a side surface of the lower container 202b, and the wafer 200 moves between vacuum conveyance chambers (not shown) via the substrate loading/unloading port 206. A plurality of lift pins 207 are installed at a bottom section of the lower container 202b.

A substrate placing section 210 configured to support the wafer 200 is installed in the processing chamber 201. The substrate placing section 210 includes a placing surface 211 on which the wafer 200 is placed, and a substrate placing frame 212 having the placing surface 211 formed on a surface thereof. In addition, a heater 213 serving as a heating member is installed. As the heating member is installed to heat the wafer 200, quality of a film formed on the wafer 200 can be improved. Through-holes 214 through which the lift pins 207 pass may be installed at the substrate placing frame 212 at positions corresponding to the lift pins 207.

The substrate placing frame 212 is supported by a shaft 217. The shaft 217 passes a bottom section of the processing container 202, and is connected to an elevation mechanism 218 at the outside of the processing container 202. As the elevation mechanism 218 is operated to elevate the shaft 217 and the substrate placing frame 212, the wafer 200 placed on the substrate placing surface 211 can be elevated. In addition, a periphery of a lower end section of the shaft 217 is coated with a bellows 219, and the inside of the processing chamber 201 is hermetically sealed.

The substrate placing frame 212 is lowered such that the substrate placing surface 211 is disposed at a position (a wafer conveyance position) of the substrate loading/unloading port 206 upon conveyance of the wafer 200, and the wafer 200 is raised to a processing position (a wafer processing position) in the processing chamber 201 as shown in FIG. 11 upon the processing of the wafer 200.

Specifically, when the substrate placing frame 212 is lowered to the wafer conveyance position, the upper end sections of the lift pins 207 protrude from the upper surface of the substrate placing surface 211 such that the lift pins 207 support the wafer 200 from below. In addition, when the substrate placing frame 212 is raised to the wafer processing position, the lift pins 207 are retracted from the upper surface of the substrate placing surface 211 such that the substrate placing surface 211 supports the wafer 200 from below. In addition, since the lift pins 207 come in direct contact with the wafer 200, the lift pins 207 may be formed of a material such as quartz, alumina, or the like. In addition, an elevation mechanism may be installed at the lift pins 207 to relatively move the substrate placing frame 212 and the lift pins 207.

The heater 213 has a configuration in which the central surface serving as a center of the wafer 200 and the outer peripheral portion of the surface of the substrate serving as an outer circumference of the central surface can be individually heated. For example, the heater 213 includes a center zone heater 213a installed at a center of the substrate placing surface 211 and having a circumferential shape when seen from above, and an outer zone heater 213b installed at an outer circumference of the center zone heater 213a and having a circumferential shape. The center zone heater 213a heats the central surface of the wafer, and the outer zone heater 213b heats the outer peripheral portion of the surface of the substrate of the wafer.

The center zone heater 213a and the outer zone heater 213b are connected to a heater temperature control member 215 via heater power supply lines, respectively. The heater temperature control member 215 controls supply of power to the heaters to control temperatures of the central surface of the wafer 200 and the outer peripheral portion of the surface of the substrate.

A temperature measurement instrument 216a and a temperature measurement instrument 216b configured to measure temperatures of the wafer 200 are contained in the substrate placing frame 212. The temperature measurement instrument 216a is installed at a center portion of the substrate placing frame 212 to measure a temperature in the vicinity of the center zone heater 213a. The temperature measurement instrument 216b is installed at the outer peripheral portion of the surface of the substrate of the substrate placing frame 212 to measure a temperature in the vicinity of the outer zone heater 213b. The temperature measurement instrument 216a and the temperature measurement instrument 216b are connected to a temperature information reception member 216c. The temperatures measured by the temperature measurement instruments are transmitted to the temperature information reception member 216c. The temperature information reception member 216c transmits the received temperature information to a controller 260 (to be described below). The controller 260 controls the temperature of the heater based on the received temperature information and the film thickness information received from an upstream apparatus 270. In addition, the temperature measurement instrument 216a, the temperature measurement instrument 216b and the temperature information reception member 216c are referred to as a temperature detector 216.

### (Exhaust System)

An exhaust port 221 configured to exhaust the atmosphere of the processing chamber 201 is installed at an upper surface of an inner wall of the processing chamber 201 (the upper container 202a). An exhaust pipe 224 serving as a first exhaust pipe is connected to the exhaust port 221, and a pressure regulator 222 such as an automatic pressure controller (APC) and a vacuum pump 223 that are configured to control the inside of the processing chamber 201 to a predetermined pressure are sequentially connected to the exhaust pipe 224 in series. A first exhaust member (an exhaust line) is mainly constituted by the exhaust port 221, the exhaust pipe 224 and the pressure regulator 222. In addition, the vacuum pump 223 may be included in the first exhaust member.

### (Buffer Chamber)

A buffer chamber 232 is installed over the processing chamber 201. The buffer chamber 232 is constituted by a sidewall 232a and a ceiling 232b. The buffer chamber 232 includes a shower head 234. A gas supply path 235 is defined by the sidewalls 232a of the buffer chamber 232 and the shower head 234. That is, the gas supply path 235 is installed to surround a sidewall 234b of the shower head 234.

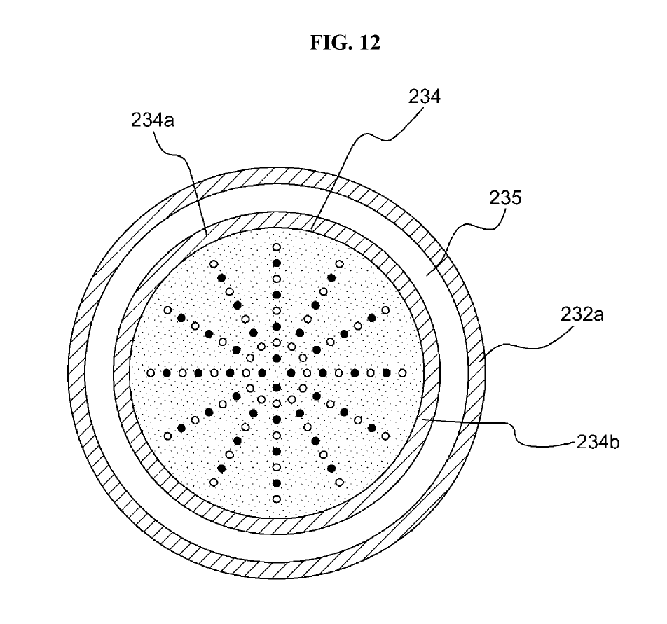

A dispersion plate 234a is installed at a wall configured to partition the shower head 234 and the processing chamber 201. The dispersion plate 234a is formed in, for example, a disk shape. When seen from the processing chamber 201 side, as shown in FIG. 12, the gas supply path 235 is installed around the dispersion plate 234a in a horizontal direction between the sidewall 234b of the shower head 234 and the sidewall 232a of the buffer chamber 232.

A gas introduction pipe 236 and a gas introduction pipe 237 pass through the ceiling 232b of the buffer chamber 232. In addition, a gas introduction pipe 238 and a gas introduction pipe 239 are connected to the ceiling 232b. The gas introduction pipe 236 and the gas introduction pipe 237 are connected to the shower head 234. The gas introduction pipe 236 and the gas introduction pipe 238 are connected to a first gas supply system (a first gas supply member), which will be described below. The gas introduction pipe 237 and the gas introduction pipe 239 are connected to a second gas supply system (a second gas supply member), which will be described below.

A gas introduced through the gas introduction pipe 236 and the gas introduction pipe 237 is supplied into the processing chamber 201 via the shower head 234. A gas introduced through the gas introduction pipe 238 and the gas introduction pipe 239 is supplied into the processing chamber 201 via the gas supply path 235.

A gas supplied from the shower head 234 is supplied onto a center of the wafer 200. A gas supplied from the gas supply path 235 is supplied onto an edge of the wafer 200. The outer peripheral portion (the edge) of the surface of the wafer is referred to as an outer circumference with respect to the center of the above-mentioned wafer. The shower head 234 is formed of a material such as quartz, alumina, stainless steel, aluminum, or the like.

### Gas Supply System (Gas Supply Member)

### (First Gas Supply System)

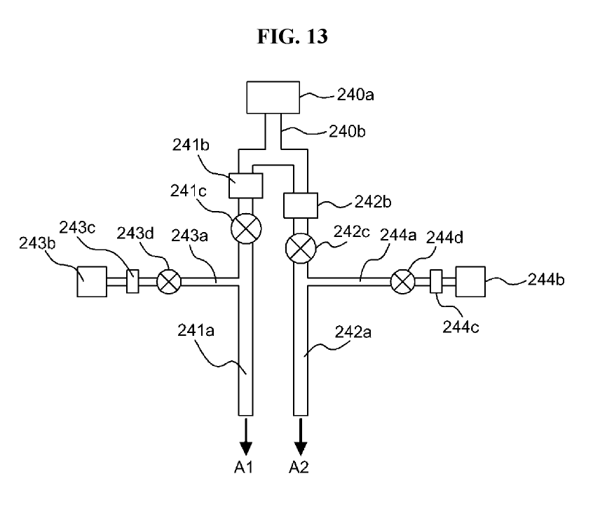

Next, the first gas supply system will be described with reference to FIG. 13. A1 of FIG. 13 is connected to A1 of FIG. 11, and A2 of FIG. 13 is connected to A2 of FIG. 11. That is, a gas supply pipe 241a is connected to the gas introduction pipe 236, and a gas supply pipe 242a is connected to the gas introduction pipe 238.

A joining pipe 240b, a mass flow controller 241b and a valve 241c are installed at the gas supply pipe 241a from an upstream side thereof. A flow rate of the gas passing through the gas supply pipe 241a is controlled by the mass flow controller 241b and the valve 241c. A first processing gas source 240a is installed at the upstream side of the joining pipe 240b.

The first processing gas is one of source material gases, i.e., processing gases. Here, a first element is, for example, silicon (Si). That is, the first processing gas is, for example, a silicon-containing gas. For example, a disilane (Si₂H₆) gas is used as the silicon-containing gas. In addition to the disilane, TEOS [Tetraethyl orthosilicate, Si(OC₂H₅)₄], (bistertiary butylamino) silane[SiH₂(NH(C₄H₉)₂, Abbreviation: BTBAS], tetrakisdimethylaminosilane (Si[N(CH₃)₂]₄, Abbreviation: 4DMAS) gas, bisdiethylaminosilane (Si[N(C₂H₅)₂]₂H₂, Abbreviation: 2DEAS) gas, bistertiary butylaminosilane (SiH₂[NH(C₄H₉)]₂, Abbreviation: BTBAS) gas, hexamethyldisilazane (C₆H₁₉NSi₂, Abbreviation: HMIDS), trisilylamine ((SiH₃)₃N, Abbreviation: TSA), hexachlorodisilane (Si₂Cl₆, Abbreviation: HCDS), and so on, may be used as the silicon-containing gas. In addition, a source material of the first processing gas may be any one of a solid, a liquid and a gas at a normal temperature and a normal pressure. When the first processing gas source material is a liquid at a normal temperature and a normal pressure, an evaporator (not shown) may be installed between a first gas supply source 243b and an MFC 243c. Here, the source material will be described as a gas.

Preferably, a first inert gas supply pipe 243a configured to supply an inert gas is connected to a downstream side of the valve 241c. An inert gas source 243b, a mass flow controller 243c and a valve 243d are installed at the first inert gas supply pipe 243a from an upstream side thereof. For example, helium (He) gas is used as the inert gas. The inert gas is added to a gas flowing through the gas supply pipe 241a to be used as a dilution gas. A concentration or a flow rate of the processing gas supplied via the gas introduction pipe 236 and the shower head 234 can be more optimally tuned by controlling the mass flow controller 243c and the valve 243d.

The joining pipe 240b, a mass flow controller 242b and a valve 242c are installed at the gas supply pipe 242a to which the gas introduction pipe 238 is connected from an upstream side thereof. A flow rate of the gas passing through the gas supply pipe 242a is controlled by the valve 242c and the mass flow controller 242b. The first processing gas source 240a is installed at an upstream side of the joining pipe 240b.

Preferably, a second inert gas supply pipe 244a configured to supply an inert gas is connected to a downstream side of the valve 242c. An inert gas source 244b, a mass flow controller 244c and a valve 244d are installed at the second inert gas supply pipe 244a from an upstream side thereof. For example, helium (He) gas is used as the inert gas. The inert gas is added to the gas flowing through the gas supply pipe 242a to be used as a dilution gas. A concentration or a flow rate of the gas flowing through the gas introduction pipe 238 and the gas supply path 235 can be more optimally tuned by controlling the mass flow controller 244c and the valve 244d.

The gas supply pipe 241a, the mass flow controller 241b, the valve 241c, the gas supply pipe 242a, the mass flow controller 242b, the valve 242c and the joining pipe 240b are referred to as the first gas supply system. In addition, the first processing gas source 240a, the gas introduction pipe 236 and the gas introduction pipe 238 may be included in the first gas supply system.

The first inert gas supply pipe 243a, the mass flow controller 243c, the valve 243d, the second inert gas supply pipe 244a, the mass flow controller 244c and the valve 244d are referred to as a first inert gas supply system. In addition, the inert gas source 243b and the inert gas source 244b may be included in the first inert gas supply system. In addition, the first gas supply system may include the first inert gas supply system.

### (Second Gas Supply System)

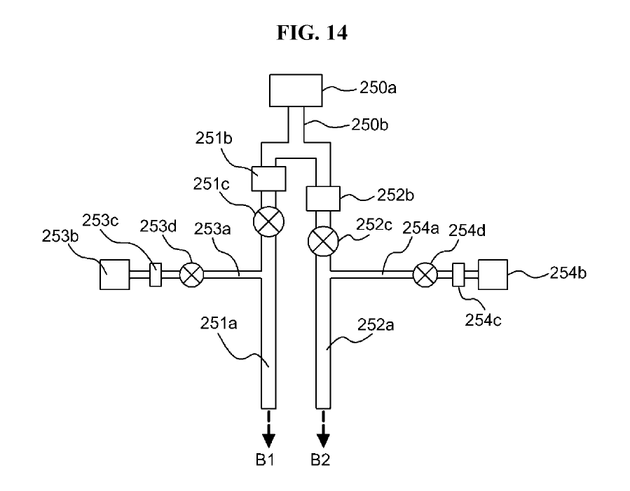

Next, the second gas supply system will be described with reference to FIG. 14. B1 of FIG. 14 is connected to B1 of FIG. 11, and B2 is connected to B2 of FIG. 11. That is, a gas supply pipe 251a is connected to the gas introduction pipe 237, and a gas supply pipe 252a is connected to the gas introduction pipe 239.

A joining pipe 250b, a mass flow controller 251b and a valve 251c are installed at the gas supply pipe 251a from an upstream side thereof. A flow rate of the gas passing through the gas supply pipe 251a is controlled by the mass flow controller 251b and the valve 251c. A second processing gas source 250a is installed at an upstream side of the joining pipe 250b.

Here, the second processing gas contains a second element different from the first element. The second element is any one of, for example, nitrogen (N), carbon (C) and hydrogen (H). In the embodiment, a nitrogen-containing gas serving as a nitration source of silicon is used. Specifically, ammonia (NH₃) gas is used as the second processing gas. A gas including a plurality of such elements may be used as the second processing gas.

Preferably, a third inert gas supply pipe 253a configured to supply an inert gas is installed at a downstream side of the valve 251c. An inert gas source 253b, a mass flow controller 253c and a valve 253d are installed at the third inert gas supply pipe 253a from an upstream side thereof. For example, helium (He) gas is used as the inert gas. The inert gas is used as a dilution gas of the gas flowing through the gas supply pipe 251a. A concentration or a flow rate of the gas supplied via the gas introduction pipe 237 and the shower head 234 can be more optimally tuned by controlling the mass flow controller 253c and the valve 253d.

The joining pipe 250b, a mass flow controller 252b and a valve 252c are installed at the gas supply pipe 252a from an upstream side thereof. A flow rate of the gas flowing through the gas supply pipe 252a is controlled by the mass flow controller 252b and the valve 252c. The second processing gas source 250a is installed at an upstream side of the joining pipe 250b.

Preferably, a fourth inert gas supply pipe 254a configured to supply an inert gas is installed at a downstream side of the valve 252c. An inert gas source 254b, a mass flow controller 254c and a valve 254d are installed at the fourth inert gas supply pipe 254a from an upstream side thereof. For example, helium (He) gas is used as the inert gas. The inert gas is used as a dilution gas of the gas flowing through the gas supply pipe 252a. A concentration or a flow rate of the gas flowing through the gas introduction pipe 239 and the gas supply path 235 can be more optimally tuned by controlling the mass flow controller 254c and the valve 254d.

The gas supply pipe 251a, the mass flow controller 251b, the valve 251c, the gas supply pipe 252a, the mass flow controller 252b, the valve 252c and the joining pipe 250b are referred to as the second gas supply system. In addition, the second processing gas source 250a, the gas introduction pipe 237 and the gas introduction pipe 239 may be included in the second gas supply system.

The third inert gas supply pipe 253a, the mass flow controller 253c, the valve 253d, the fourth inert gas supply pipe 254a, the mass flow controller 254c and the valve 254d are referred to as a second inert gas supply system. In addition, the inert gas source 253b and the inert gas source 254b may be included in the second inert gas supply system. In addition, the second gas supply system may include the second inert gas supply system. In addition, the first gas supply system and the second gas supply system are referred to as the gas supply system.

As described above, since the mass flow controllers and the valves are installed at the first gas supply system and the second gas supply system, amounts of gases can be individually controlled. In addition, since the mass flow controllers and the valves are installed at the first inert gas supply system and the second inert gas supply system, concentrations of gases can be individually controlled.

### (Control Member)

The substrate processing apparatus 900 includes the controller 260 configured to control operations of the respective units of the substrate processing apparatus 900.

The controller 260 is shown in FIG. 15 in brief. The controller 260 serving as a control member (a control means) is configured as a computer including a central processing unit (CPU) 260a, a random access memory (RAM) 260b, a storage device 260c and an I/O port 260d. The RAM 260b, the storage device 260c and the I/O port 260d are configured to exchange data with the CPU 260a via an internal bus 260e. An input/output device 261 constituted by, for example, a touch panel, or the like, or an external storage device 262 can be connected to the controller 260. In addition, a receiving member 263 connected to the upstream apparatus 270 via a network is installed. The receiving member 263 can receive information of another apparatus from the upstream apparatus 270.

The storage device 260c is constituted by, for example, a flash memory, a hard disk drive (HDD), and so on. A control program configured to control an operation of the substrate processing apparatus, a program recipe on which a sequence, a condition, or the like, of the substrate processing (to be described below) is described, and so on, are readably stored in the storage device 260c. In addition, process recipes are combined to perform sequences in the following substrate processing process by the controller 260 to obtain a predetermined result, and functions as a program. Hereinafter, the program recipe, the control program, or the like, is generally and simply referred to as a program. In addition, when the term “program” is used herein, the program may include solely a program recipe, a control program, both of these. In addition, the RAM 260b is configured as a work area in which a program, data, or the like, read by the CPU 260a is temporarily stored.

The I/O port 260d is connected to the gate valve 205, the elevation mechanism 218, the heater 213, the pressure regulator 222, the vacuum pump 223, and so on. In addition, the I/O port 260d may be connected to the MFCs 241b, 242b, 243c, 244c, 251b, 252b, 253c and 254c, the valves 241c, 242c, 243d, 244d, 251c, 252c, 253d and 254d, and so on.

The CPU 260a is configured to read the process recipe from the storage device 260c according to input of an operation command from the input/output device 261 while reading and performing the control program from the storage device 260c. In addition, the CPU 260a is configured to control an opening/closing operation of the gate valve 205, an elevation operation of the elevation mechanism 218, a power supply operation to the heater 213, a pressure regulation operation of the pressure regulator 222, ON/OFF control of the vacuum pump 223, a flow rate regulation operation of the mass flow controller, an operation of the valve, and so on, to follow the contents of the read process recipe.

In addition, the controller 260 is not limited to the case constituted by a dedicated computer but may be constituted by a general-purpose computer. For example, the controller 260 according to the embodiment may be configured by preparing the external storage device 262 in which the above-mentioned program is stored (for example, a magnetic tape, a magnetic disk such as a flexible disk, a hard disk or the like, an optical disc such as CD, DVD or the like, an optical magnetic disk such as MO, a semiconductor memory such as a USB memory, a memory card or the like), and installing the program in the general-purpose computer using the external storage device 262. In addition, a means configured to supply a program to a computer is not limited to the case in which the program is supplied via the external storage device 262. For example, the program may be supplied using a communication means such as the Internet, an exclusive line, or the like, without intervention of the external storage device 262. In addition, the storage device 260c or the external storage device 262 is constituted by a computer-readable recording medium. Hereinafter, these are generally and simply referred to as a recording medium. In addition, when the term “recording medium” is used herein, the recording medium may include solely the storage device 260c, solely the external storage device 262, or both of these.

In addition, while the receiving member of the embodiment has been described as receiving information of another device from the upstream apparatus 270, the embodiment is not limited thereto. For example, the information may be directly received from other devices. In addition, information of another device may be input by the input/output device 261, and the control may be performed based on the information. In addition, the information of the other device may be stored in the external storage device, and the information of the other device may be received from the external storage device.

Next, a method of forming the hard mask film 2006 using the substrate processing apparatus 900 will be described with reference to FIG. 22. After the film thickness measurement process (S104), the measured wafer 200 is loaded into the substrate processing apparatus 900. In addition, in the following description, operations of the components that constitute the substrate processing apparatus are controlled by the controller 260.

### Substrate Loading Process (S201)

After film thickness distribution of a silicon oxide film 2005 is measured in the film thickness measurement process (S104), the wafer 200 is loaded into the substrate processing apparatus 900. Specifically, the substrate placing section 210 is lowered by the elevation mechanism 218 such that the lift pins 207 protrude toward the upper surface of the substrate placing section 210 through the through-holes 214. In addition, after the inside of the processing chamber 201 is regulated to a predetermined pressure, the gate valve 205 is opened to place the wafer 200 on the lift pins 207 from the gate valve 205. After the wafer 200 is placed on the lift pins 207, as the elevation mechanism 218 raises the substrate placing section 210 to a predetermined position, the wafer 200 is placed on the substrate placing section 210 from the lift pins 207.

### Decompression/Temperature Elevating Process (S202)

Next, the inside of the processing chamber 201 is exhausted via the exhaust pipe 224 such that the inside of the processing chamber 201 becomes a predetermined pressure (a vacuum level). Here, a pressure sensor feedback-controls an opening degree of the APC valve serving as the pressure regulator 222 based on the pressure value measured by the pressure sensor. In addition, an energization quantity to the heater 213 is feedback-controlled such that the inside of the processing chamber 201 becomes a predetermined temperature based on the temperature value detected by a temperature sensor 216. Specifically, the substrate placing section 210 is preheated by the heater 213, and left for a predetermined time after a variation in temperature of the wafer 200 or the substrate placing section 210 is disappeared. During the predetermined time, when degassing or the like occurs from the moisture or the member remaining in the processing chamber 201, the gas may be removed through vacuum exhaust or purging by supply of the inert gas. As a result, preparation before a film forming process is completed. In addition, when the inside of the processing chamber 201 is exhausted to a predetermined pressure, the vacuum exhaust may be performed to a vacuum level once.

After the wafer 200 is placed on the substrate placing section 210 and the atmosphere in the processing chamber 201 is stabilized, opening degrees of the valves 241c, 242c, 251c and 252c are adjusted while operating the mass flow controllers 241b, 242b, 251b and 252b. Here, the opening degrees of the valves 243d, 244d, 253d and 254d may be adjusted while operating the mass flow controllers 243c, 244c, 253c and 254c.

### Gas Supply Process (S203)

A gas is supplied into the processing chamber 201 from the first gas supply system and the second gas supply system in the gas supply process.

When the gas is supplied, the mass flow controllers or the valves of the first gas supply system and the second gas supply system are controlled according to film thickness measurement data of an insulating film 2013 received from the upstream apparatus 270 through the data receiving process S200 to control an amount (or a concentration) of a processing gas supplied onto the center portion of the wafer 200 and an amount (or a concentration) of a processing gas supplied onto the outer peripheral portion of the surface of the substrate. More preferably, the center zone heater 213a and the outer zone heater 213b are controlled according to the measurement data received from the upstream apparatus 270 to control the temperature distribution on the wafer 200.

The gas supplied into the processing chamber 201 is decomposed in the processing chamber 201 to form the hard mask film 2006 on the silicon oxide film 2005 after the polishing.

After the predetermined time elapses, the valves are closed to stop the supply of the gas.

The temperature of the heater 213 at this time is a temperature that does not exert a bad influence on the already formed configuration. For example, the temperature is set such that the wafer 200 becomes a predetermined temperature within a range of 300° C. to 450° C.

In addition to He gas, a gas that does not exert a bad influence on the film may be used as the inert gas, and for example, a rare gas such as Ar, N₂, Ne, Xe, and so on, may be used.

### Substrate Unloading Process (S204)

After the gas supply process S203 is completed, the substrate placing section 210 is lowered by the elevation mechanism 218 such that the lift pins 207 protrude from the through-holes 214 toward the upper surface of the substrate placing section 210. In addition, after the inside of the processing chamber 201 is regulated to a predetermined pressure, the gate valve 205 is opened and the wafer 200 is conveyed to the outside of the gate valve 205 from above the lift pins 207.

Next, a method of controlling a film thickness of the hard mask film 2006 using the apparatus will be described. As described above, after the polishing process (S103) is completed, the film thickness of the poly-Si film 2005 varies at the center portion of the wafer 200 and the outer peripheral portion of the surface of the substrate. In the film thickness measurement process (S104), the film thickness distribution is measured. The measurement result is stored in the RAM 260b through the upstream apparatus 270. The stored data are compared with the recipe in the storage device 260c to control the apparatus based on the recipe, and the film thickness distribution is adjusted (tuned).

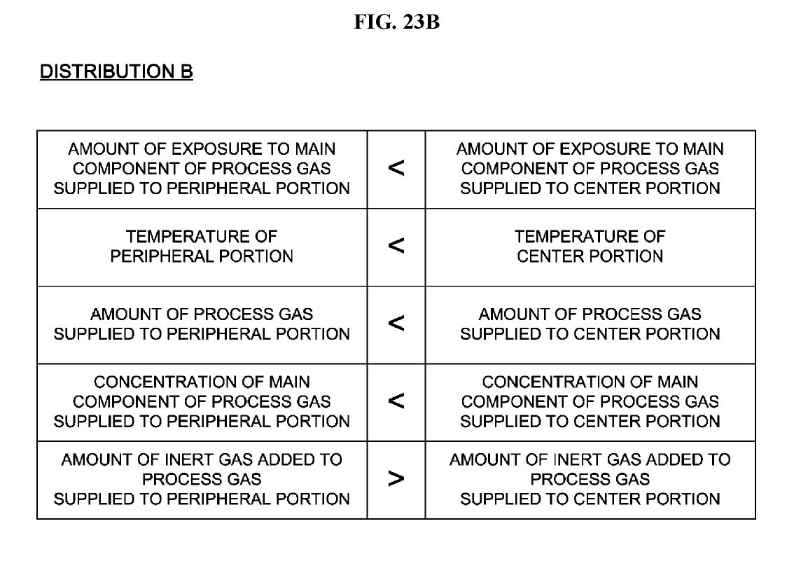

Next, the case in which the data stored in the RAM 260b is the distribution A will be described with reference to FIG. 23A. The case of the distribution A is referred to as the case in which a poly-Si film 2005c is thicker than a poly-Si film 2005d as shown in FIGS. 7B and 8.

In the case of the distribution A, in the process, the hard mask film 2006b formed on the outer peripheral portion of the surface of the wafer 200 is thickened, and the film thickness of the hard mask film 2006a formed on the center portion of the wafer 200 is controlled to be smaller than that of the hard mask film 2006b. Specifically, when the gas is supplied, an amount of the silicon-containing gas supplied onto the outer peripheral portion of the surface of the wafer 200 is controlled to be larger than the center portion of the wafer 200. Accordingly, the height of the surface of the hard mask film in the semiconductor device, i.e., a film thickness of a deposition film obtained by overlapping the hard mask film 2006 on the poly-Si film 2005 can be adjusted like the film thickness distribution A′ shown in FIG. 8. That is, the film thickness of the deposition film can be corrected like the film thickness distribution A′.

Here, in the first gas supply system, an opening degree of the valve 241c is controlled to control an amount of the silicon-containing gas supplied from the shower head 234 into the processing chamber 201 while controlling the mass flow controller 241b. In addition, an opening degree of the valve 242c is controlled to supply the silicon-containing gas from the gas supply path 235 into the processing chamber 201 while controlling the mass flow controller 242b. An exposure quantity of the silicon-containing gas per unit area in a processing surface of the wafer 200 is controlled such that the exposure quantity of the gas supplied from the gas supply path 235 is larger than the exposure quantity of the gas supplied from the shower head 234. The exposure quantity disclosed herein is referred to as the exposure quantity of the processing gas with respect to a major element. In the embodiment, the processing gas is the silicon-containing gas, a major element of which is silicon.

In addition, in the second gas supply system, an opening degree of the valve 251c is controlled to control an amount of the nitrogen-containing gas supplied from the shower head 234 while controlling the mass flow controller 251b. The amount of the nitrogen-containing gas in the gas supply pipe 251a is an amount corresponding to the amount of the silicon-containing gas in the gas supply pipe 241a. In addition, an opening degree of the valve 252c is controlled to supply the nitrogen-containing gas from the gas supply path 235 while controlling the mass flow controller 252b. The amount of the nitrogen-containing gas in the gas supply pipe 252a is an amount corresponding to the silicon-containing gas in the gas supply pipe 242a.

Here, the exposure quantity of the silicon-containing gas per unit area in the processing surface of the wafer 200 is controlled such that the exposure quantity of the gas supplied from the gas supply path 235 is larger than the exposure quantity of the gas supplied from the shower head 234. The exposure quantity disclosed herein is referred to as the exposure quantity of the processing gas with respect to the major element. In the embodiment, the processing gas is the silicon-containing gas, a major element of which is silicon.

The silicon-containing gas and the nitrogen-containing gas supplied via the shower head 234 are supplied onto the poly-Si film 2005c formed on the center portion of the wafer 200. As shown in FIG. 7B, the supplied gas forms the hard mask film 2006a on the poly-Si film 2005c.

The silicon-containing gas and the nitrogen-containing gas supplied via the gas supply path 235 are supplied onto the poly-Si film 2005d formed on the outer peripheral portion of the surface of the wafer 200. As shown in FIG. 7B, the supplied gas forms the hard mask film 2006b on the poly-Si film 2005d.

As described above, since the exposure quantity of the silicon-containing gas per unit area in the processing surface of the wafer 200 is larger than that of the poly-Si film 2005c on the poly-Si film 2005d, the film thickness of the hard mask film 2006b may be larger than that of the hard mask film 2006a.

Here, as shown in FIG. 7B, the thickness of the hard mask film 2006 is controlled such that the height H1b from the concave structure surface 2002a in the outer peripheral portion of the surface of the wafer 200 to the upper end of the hard mask film 2006b is substantially equal to the height H1a from the concave structure surface 2002a in the center portion of the wafer 200 to the upper end of the hard mask film 2006a. More preferably, the thickness of the hard mask film 2006 is controlled such that a difference between a distance from the surface of the wafer 200 to the upper end of the hard mask film 2006b and a distance from the surface of the wafer 200 to the upper end of the hard mask film 2006a is within a predetermined range. In addition, more preferably, the film thickness distribution of the hard mask film 2006 is controlled such that the height of the surface (the upper surface) of the hard mask film 2006 of the surface of the substrate is within a predetermined range.

In addition, as another method, supply amounts of the silicon-containing gases of the gas supply pipe 241a and the gas supply pipe 242a are similar, and instead of this, the concentrations of the silicon-containing gases of the gas supply pipe 241a and the gas supply pipe 242a may be controlled. When the concentration of the silicon-containing gas is controlled, the concentrations of the silicon-containing gases passing through the gas supply pipe 241a and the gas supply pipe 242a are controlled by controlling the first inert gas supply system. In the case of the distribution A, while reducing the concentration of the silicon-containing gas passing through the gas supply pipe 241a, the concentration of the silicon-containing gas passing through the gas supply pipe 242a is increased to be larger than the concentration of the gas passing through the gas supply pipe 241a.

As a result, the exposure quantity of the silicon-containing gas per unit area in the processing surface of the wafer 200 can be more precisely controlled such that the amount of the gas supplied from the gas supply path 235 is larger than the amount of the gas supplied from the shower head 234. Accordingly, the film thickness of the hard mask film 2006b can be more securely increased to be larger than that of the hard mask film 2006a.

More preferably, the concentrations may be varied while varying the supply amounts of the silicon-containing gases of the gas supply pipe 241a and the gas supply pipe 242a. As a result, the exposure quantity of the silicon-containing gas per unit area can be supplied with a larger incremental difference. That is, the difference between the film thicknesses of the hard mask film 2006a and the hard mask film 2006b can be further increased. Accordingly, even when the height difference between the surfaces (the upper surfaces) of the poly-Si film 2005c and the poly-Si film 2005d is increased in the polishing process (S103), the heights of the surfaces (the upper surfaces) of the hard mask film 2006a and the hard mask film 2006b can be matched.

In addition, more preferably, as described above, the center zone heater 213a and the outer zone heater 213b may be controlled while controlling the processing gas. Since the formed film thickness is in proportion to the temperature, in the case of the distribution A, the temperature of the outer zone heater 213b is higher than that of the center zone heater 213a. For example, this is effective in the case in which the hard mask film 2006 is formed using a gas such as the disilane gas whose temperature condition largely contributes to film generating efficiency.

As described above, when the supply amount (the concentration) and the temperature of the processing gas are controlled in parallel, more precise film thickness control becomes possible.

Next, the case in which the data stored in the RAM 260b is the distribution B will be described with reference to FIG. 23B. The case of the distribution B is referred to as the case in which the poly-Si film 2005d is thicker than the poly-Si film 2005c as shown in FIGS. 9B and 10.

In the case of the distribution B, in the process, the hard mask film 2006a formed at the center portion of the wafer 200 is thickened, and the film thickness of the hard mask film 2006b formed at the outer peripheral portion of the surface of the wafer 200 is controlled to become smaller than that of the hard mask film 2006a. Specifically, when the gas is supplied, the silicon-containing gas supplied onto the center portion of the wafer 200 is controlled to become more than the outer peripheral portion of the surface of the wafer 200. As a result, the height of the surface (the upper surface) of the insulating film in the semiconductor device, i.e., the height of the insulating film 2013 overlapping with the hard mask film 2006 can be corrected like the target film thickness distribution B′ shown in FIG. 10. That is, the film thickness of the deposition film can be corrected like the film thickness distribution B′.

Here, in the first gas supply system, the opening degree of the valve 241c is controlled to control the amount of the silicon-containing gas supplied from the shower head 234 into the processing chamber 201 while controlling the mass flow controller 241b. In addition, the opening degree of the valve 242c is controlled to supply the silicon-containing gas from the gas supply path 235 into the processing chamber 201 while controlling the mass flow controller 242b. The exposure quantity of the silicon-containing gas per unit area in the processing surface of the wafer 200 is controlled such that the exposure quantity of the gas supplied from the shower head 234 is larger than the exposure quantity of the gas supplied from the gas supply path 235.

In addition, in the second gas supply system, the opening degree of the valve 251c is controlled to control the amount of the nitrogen-containing gas supplied from the shower head 234 while controlling the mass flow controller 251b. The amount of the nitrogen-containing gas in the gas supply pipe 251a is an amount corresponding to the amount of the silicon-containing gas in the gas supply pipe 241a. In addition, the opening degree of the valve 252c is controlled to supply the nitrogen-containing gas from the gas supply path 235 while controlling the mass flow controller 252b. The amount of the nitrogen-containing gas in the gas supply pipe 252a is an amount corresponding to the amount of the silicon-containing gas in the gas supply pipe 242a.

Here, the exposure quantity of the silicon-containing gas per unit area in the processing surface of the wafer 200 is controlled such that the exposure quantity of the gas supplied from the shower head 234 is larger than the exposure quantity of the gas supplied from the gas supply path 235.

The silicon-containing gas and the nitrogen-containing gas supplied via the shower head 234 is supplied onto the poly-Si film 2005c formed at the center portion of the wafer 200. As shown in FIG. 9B, the supplied gas forms the hard mask film 2006a on the poly-Si film 2005c.

The silicon-containing gas and the nitrogen-containing gas supplied via the gas supply path 235 are supplied onto the poly-Si film 2005d formed at the outer peripheral portion of the surface of the wafer 200. As shown in FIG. 9B, the supplied gas forms the hard mask film 2006b on the poly-Si film 2005d.

As described above, since the exposure quantity of the silicon-containing gas per unit area in the processing surface of the wafer 200 is increased on the poly-Si film 2005c more than on the poly-Si film 2005d, the film thickness of the hard mask film 2006a may be larger than that of the hard mask film 2006b.

Here, as shown in FIG. 9B, the thickness of the hard mask film 2006 is controlled such that the height H1b from the concave structure surface 2002a in the outer peripheral portion of the surface of the wafer 200 to the upper end of the hard mask film 2006b is substantially equal to the height H1a from the concave structure surface 2002a in the center portion of the wafer 200 to the upper end of the hard mask film 2006a. More preferably, a difference between a distance between the surface of the wafer 200 to the upper end of the hard mask film 2006b and a distance from the surface of the wafer 200 to the upper end of the hard mask film 2006a is within a predetermined range. In addition, more preferably, the film thickness distribution of the hard mask film 2006 is controlled such that the height of the surface (the upper surface) of the hard mask film 2006 on the surface of the substrate is within a predetermined range.

In addition, as another method, the supply amounts of the silicon-containing gases of the gas supply pipe 241a and the gas supply pipe 242a may be similar, and instead of this, the concentrations of the silicon-containing gases of the gas supply pipe 241a and the gas supply pipe 242a may be controlled. When the concentrations of the silicon-containing gases are controlled, the concentrations of the silicon-containing gases passing through the gas supply pipe 241a and the gas supply pipe 242a can be controlled by controlling the first inert gas supply system. In the case of the distribution B, while reducing the concentration of the silicon-containing gas passing through the gas supply pipe 242a, the concentration of the silicon-containing gas passing through the gas supply pipe 241a is larger than the concentration of the gas passing through the gas supply pipe 242a.

As a result, the exposure quantity of the silicon-containing gas of unit area in the processing surface of the wafer 200 can be more securely controlled such that an amount of the gas supplied from the shower head 234 is larger than an amount of the gas supplied from the gas supply path 235. Accordingly, the film thickness of the hard mask film 2006a can be more securely increased to be larger than that of the hard mask film 2006b.

More specifically, the concentrations may be different while varying the supply amounts of the silicon-containing gases of the gas supply pipe 251a and the gas supply pipe 252a. As a result, the exposure quantity of the silicon-containing gas per unit area can be supplied with a large incremental difference. That is, a difference in film thickness between the hard mask film 2006a and the hard mask film 2006b can be further increased. Accordingly, even when a difference between the height of the surface of the poly-Si film 2005c and the height of the surface of the poly-Si film 2005d is increased in the polishing process (S103), the heights of the surfaces (the upper surfaces) of the hard mask film 2006a and the hard mask film 2006b on the wafer 200 can be matched.

In addition, more preferably, as described above, the center zone heater 213a and the outer zone heater 213b can be controlled while controlling the processing gas. Since the formed film thickness is in proportion to the temperature, in the case of the distribution B, the temperature of the center zone heater 213a is higher than the outer zone heater 213b. For example, this is effective in the case in which the hard mask film 2006 is formed using the gas such as the disilane gas whose temperature condition largely contributes to film generating efficiency.

As described above, when the supply amount (the concentration) and the temperature of the processing gas are controlled in parallel, more precise film thickness control becomes possible.

As described above, the thickness of the hard mask film 2006 can be controlled at a center and a periphery of the wafer 200 by tuning the amount of the silicon-containing gas per unit area of the processing surface of the wafer 200.

Here, the thickness of the hard mask film 2006 is controlled such that the thickness of the poly-Si film 2005d overlapped with the hard mask film 2006b is equal to the thickness of the poly-Si film 2005c overlapped with the hard mask film 2006a.

### Film Thickness Measurement Process (S106)

Subsequently to the hard mask film forming process (S105), the film thickness measurement process (S106) may be performed. In the film thickness measurement process (S106), the height of the surface (the upper surface) of the deposition film obtained by overlapping the silicon oxide film 2005 and the hard mask film 2006 is measured. Specifically, it is determined whether the heights of the surfaces (the upper surfaces) of the overlapped layers coincide with each other, i.e., whether the film thickness of the deposition film is corrected like the film thickness distribution of the target. Here, the phrase “the heights coincide with each other” is not limited to that the heights completely coincide with each other but a difference in height may occur. For example, the difference in height may occur as long as the difference is within a range in which there is no affection in the following patterning process or the like. The phrase “the thicknesses are equal” is also not limited to that the thicknesses are completely equal but a difference in thickness may occur. For example, the difference in thickness may occur as long as the difference is within a range in which there is no affection in the following patterning process or the like.

After the hard mask film forming process (S105), the wafer 200 is loaded into the measurement apparatus. The measurement apparatus measures at least several places in the center portion of the wafer 200 and the outer peripheral portion of the surface of the substrate that can be easily affected by the polishing apparatus 400, and measures the film thickness (height) distribution of the hard mask film 2006. The measured data are sent to the upstream apparatus 270. After the measurement, the wafer 200 was unloaded. When the height on the wafer 200 is within a predetermined range, specifically, within a range in which there is no affection in the following patterning process (S107) and so on, the patterning process (S107) is performed. In addition, when it is previously known that the film thickness distribution becomes a predetermined distribution, the film thickness measurement process (S106) may be omitted.

### Patterning Process (S107)

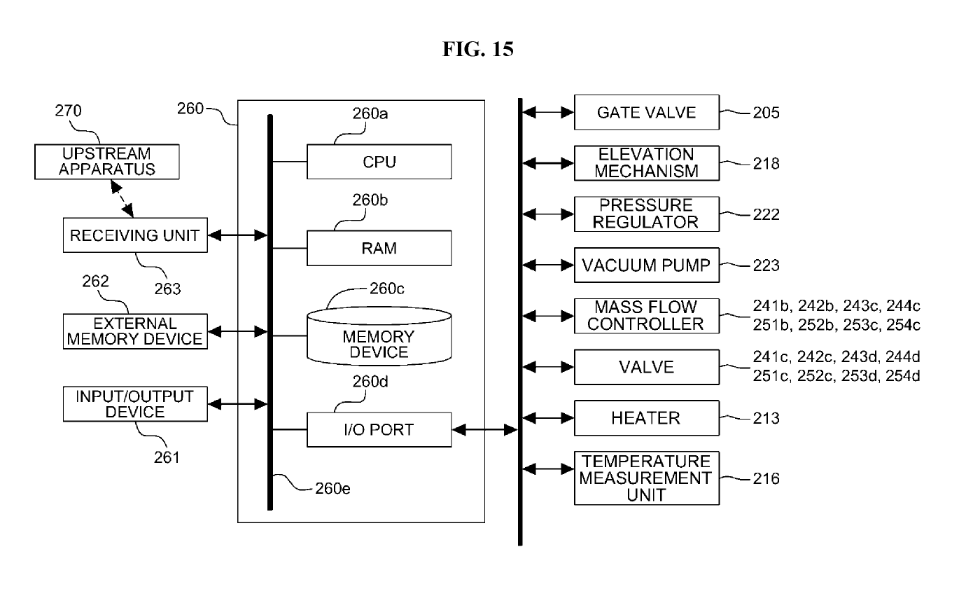

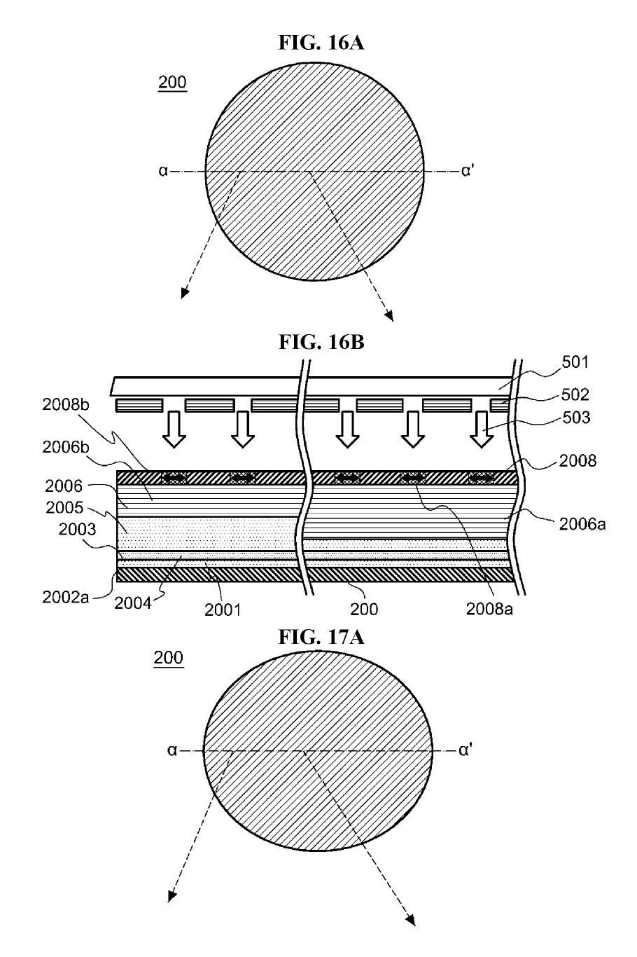

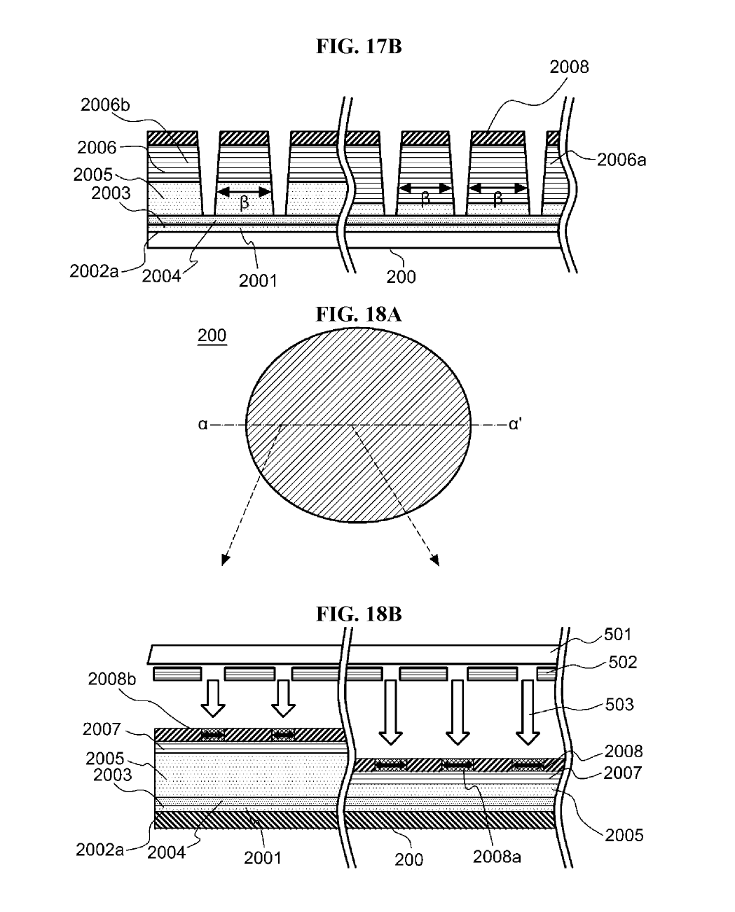

Next, the patterning process (S107) will be described with reference to FIGS. 16A through 17B. FIGS. 16A and 16B are views for describing the wafer 200 in the exposure process. FIGS. 17A and 17B are views for describing the wafer 200 after the etching process.

Hereinafter, specific description will be described. After the hard mask film 2006 is formed, a resist film 2008 is applied on the hard mask film 2006. Then, light is emitted from a lamp 501 to perform an exposure process. In the exposure process, light 503 is irradiated onto the resist film 2008 via a mask 502 to modify a portion of the resist film 2008. Here, the modified resist film is referred to as an exposed section 2008a, and the unmodified resist film is referred to as a non-exposed section 2008b.

As described above, a height from a concaved surface 2002a to the surface of the hard mask film 2006 is within a predetermined range. Accordingly, a height from the concaved surface 2002a to the resist film 2008 can be matched. In the exposure process, a distance to which the light arrives at the resist film, i.e., movement of the light 503 is equalized in the wafer 200. Accordingly, distribution of a focal depth on the surface of the substrate can be equalized.

Since the focal depth can be equalized, as shown in FIG. 16B, a width of the exposed section 2008a can be constant in the surface of the substrate. Accordingly, deviation in depth of the pattern can be removed.

Next, a state of the wafer 200 after the etching processing will be described with reference to FIGS. 17A and 17B. As described above, since the width of the exposed section 2008a is constant, the etching condition on the surface of the wafer 200 can be constant. Accordingly, an etching gas can be uniformly supplied onto the center portion of the wafer 200 or the outer peripheral portion of the surface of the substrate, and a width β of the poly-Si film (hereinafter, also referred to as “a filler”) after etching can be constant. Since the width β is constant on the wafer 200, properties of the gate electrode can be constant on the substrate to improve yield.

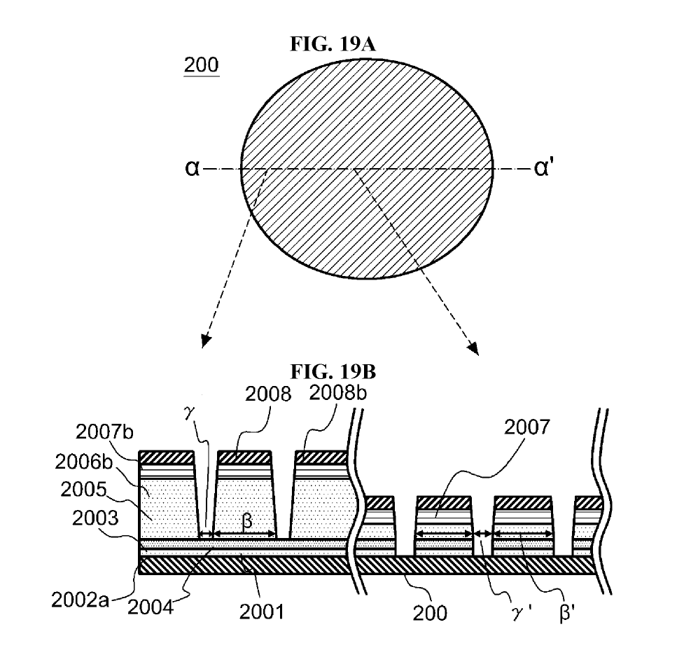

Next, a first comparative example will be described with reference to FIGS. 18A through 19B. The first comparative example is the case in which correction of the film thickness distribution is not performed in the hard mask film forming process (S105), i.e., the case in which the film thickness distribution is not adjusted (tuned). Accordingly, the heights of the surfaces are different at the center portion of the wafer 200 and the outer peripheral portion of the surface of the substrate.

First, the first comparative example will be described with reference to FIGS. 18A and 18B. FIGS. 18A and 18B are views in comparison with FIGS. 16A and 16B. In the case of FIG. 18B, the hard mask film 2006 on which correction of the film thickness distribution is not performed has substantially the same film thickness at the central side and the outer circumferential side of the wafer 200. As a result, since the heights of the surfaces (the upper surfaces) of the poly-Si film 2005 and the hard mask film 2006 are different at the center portion of the wafer 200 and the outer peripheral portion of the surface of the substrate, a distance of the light 503 is varied at the center portion of the wafer 200 and the outer peripheral portion of the surface of the substrate. Accordingly, the focal distance is varied at the center portion and the outer peripheral portion of the surface of the substrate, and as a result, the width of the exposed section 2008a is varied on the surface of the substrate. When the processing is performed using the resist film 2008, the width of the filler after the etching process is varied as shown in FIG. 19B. That is, a distance γ between the poly-Si films of the filler is varied at the center portion of the wafer 200 and the outer peripheral portion of the surface of the substrate. That is, the width β of the poly-Si film of the filler is varied at the center portion of the wafer 200 and the outer peripheral portion of the surface of the substrate.

Since the properties of the electrode are easily affected by the width β, when deviation in the width β occurs, deviation also occurs in the properties of the electrode. Accordingly, the deviation in the width β leads to reduction in yield.

On the other hand, in the embodiment, since the hard mask film forming process (S105) is performed, the width of the filler on the surface of the wafer 200 can be constant. Accordingly, since the semiconductor device having uniform properties in comparison with the comparative example can be formed, the yield can be remarkably improved.

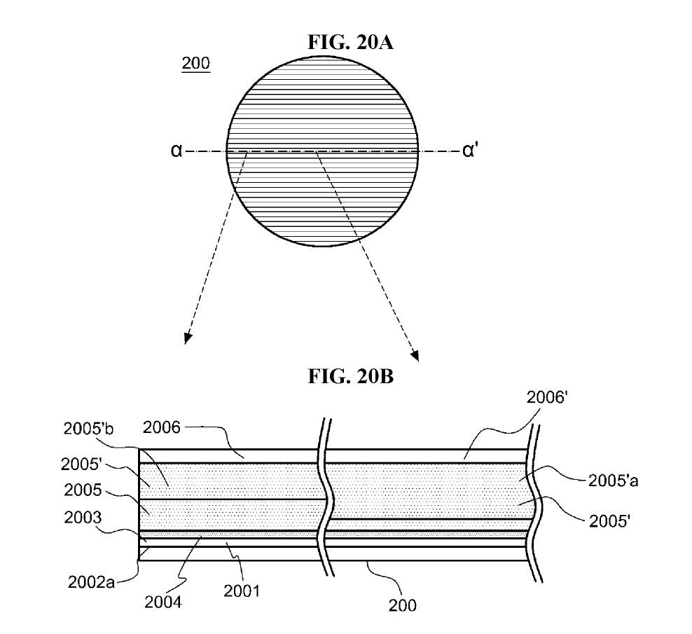

Next, a second comparative example will be described with reference to FIGS. 20A and 20B. The second comparative example presumes the case in which the film thickness distribution is A, and corrects the film thickness distribution using a method different from the embodiment. Specifically, a second poly-Si film 2005′ is formed after the film thickness measurement process (S104).

The second poly-Si film 2005′ is formed as described below. The wafer 200 on which the poly-Si film 2005 is formed is loaded into the film thickness measurement apparatus via the polishing apparatus. The film thickness distribution is measured by the film thickness measurement apparatus, and after the measurement, the wafer 200 is unloaded. The unloaded wafer is loaded into the second silicon-containing film forming apparatus, and the second poly-Si film 2005′ is formed on the poly-Si film 2005 according to the measured film thickness distribution. Here, the second poly-Si film 2005′ is formed according to the film thickness distribution data measured to remove the deviation of the film thickness distribution. As a result, the height of the surface (the upper surface) of the poly-Si film is matched.

Then, the wafer 200 is unloaded from the second silicon-containing film forming apparatus and loaded into the hard mask film forming apparatus. In the hard mask film forming apparatus, the hard mask film 2006′ is formed on the second poly-Si film 2005′.

According to the method, the height of the surface of the hard mask film 2006′ can be matched on the wafer 200.

However, as a result of research by the inventor(s) of the present invention, it was known that the following problems occur due to the technique by the second comparative example. In the second comparative example, the poly-Si film 2005 and the second poly-Si film 2005′ are formed through different processes. In addition, the polishing process (S103) is interposed between the processes. That is, the poly-Si film 2005 and the second poly-Si film 2005′ are not continuously formed even when they are formed of the same compound, and damage may occur due to the polishing. Accordingly, a film composition near an interface of the film is modified between the poly-Si film 2005 and the second poly-Si film 2005′, and thus, an interface layer having different composition from the films may be formed.

When the interface layer is formed, an etching rate is varied at an interface layer between the poly-Si film 2005 and the second poly-Si film 2005′. That is, essentially, since the poly-Si film 2005 and the second poly-Si film 2005′ are constituted by the same compound, the films should have the same etching rate. However, when the interface layer is interposed therebetween, the films does not have a uniform etching rate. Accordingly, in all of the poly-Si films, the etching rate in the patterning process cannot be easily calculated. That is, over etching, lack of etching, or the like, may occur in the patterning process.

In addition, when the interface layer is interposed between the poly-Si film 2005 and the second poly-Si film 2005′, a coupling degree therebetween may be weakened.

On the other hand, in the above-mentioned embodiment, since correction of the deviation of the film thickness distribution of the poly-Si film 2005 is performed using the SiN film 2006 serving as the hard mask film other than forming the second poly-Si film 2005′ like the second comparative example, the following risk can be reduced. That is, in the embodiment, since the interface layer like in the second comparative example is not formed in the film of the poly-Si film 2005, the etching rate with respect to the poly-Si film 2005 can be easily calculated. For this reason, a risk such as over etching, lack of etching, or the like, in the patterning process can be suppressed. In addition, in the first specific example of the embodiment, since there is no need to form the second poly-Si film 2005′, the number of processing can be reduced by one in comparison with the case of the third comparative example, and thus, high manufacturing throughput can be realized.

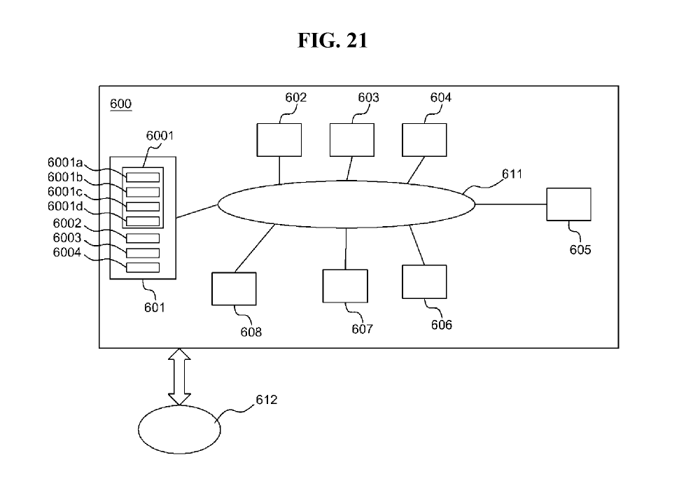

In addition, in the embodiment, while the gate insulating film forming process (S101) to the patterning process (S107) has been described as being performed by individual apparatuses, the embodiment is not limited but may be performed by one system as shown in FIG. 21. Here, a substrate processing system 600 includes an upstream apparatus 601 configured to control the apparatuses. The substrate processing system 600 includes an insulating film forming apparatus 602 configured to perform the gate insulating film forming process (S101), a substrate processing apparatus 603 configured to perform the silicon-containing film forming process (S102), a polishing apparatus 604 (corresponding to the polishing apparatus 400 of the embodiment) configured to perform the polishing process (S103), a film thickness measurement apparatus 605 configured to perform the film thickness measurement process (S104), a substrate processing apparatus 606 (corresponding to the substrate processing apparatus 900 of the embodiment) configured to perform the hard mask film forming process (S105), a film thickness measurement apparatus 607 configured to perform the film thickness measurement process (S106), and a patterning system 608 configured to perform the patterning process (S107). In addition, the substrate processing system 600 includes a network 611 configured to exchange data between the apparatuses and the systems 602 through 608.

The apparatus included in the substrate processing system 600 may be appropriately selected, and may be integrated as one apparatus when functions of the apparatuses overlap. In addition, the apparatus may be managed by another system (not shown) other than the substrate processing system 600. In this case, information transmission with another system may be performed via a network 612 of a further upstream side.

The upstream apparatus 601 includes a controller 6001 configured to control information transmission of the apparatuses or the system 602 through 608.

The controller 6001 serving as the control member (the control means) is constituted by a computer including a central processing unit (CPU) 6001a, a random access memory (RAM) 6001b, a storage device 6001c and an I/O port 6001d. The RAM 6001b, the storage device 6001c and the I/O port 6001d may be configured to exchange data with the CPU 6001a via an internal bus. An input/output device 6002 constituted by, for example, a touch panel or the like, or an external storage device 6003 can be connected to the controller 6001. In addition, a transmission/reception member 6004 configured to transmit and receive information via another apparatus or system and a network is installed.

The storage device 6001c is constituted by, for example, a flash memory, a hard disk drive (HDD), and so on. A program or the like configured to command an operation to the substrate processing apparatus is readably stored in the storage device 6001c. In addition, the RAM 6001b is configured as a work area in which the program or data read by the CPU 6001a is temporarily held.

The CPU 6001a is configured to read the program from the storage device 6001c according to input of an operation command from the input/output device 6002 while reading and executing a control program from the storage device 6001c. In addition, the CPU 6001a is configured to control an information transmission operation of each apparatus to follow contents of the read program.

In addition, the controller 6001 is not limited to the case constituted by a dedicated computer but may be constituted by a general-purpose computer. For example, the controller 6001 according to the embodiment may be configured by preparing the external storage device 6003 in which the above-mentioned program is stored (for example, a magnetic tape, a magnetic disk such as a flexible disk, a hard disk or the like, an optical disc such as CD, DVD or the like, an optical magnetic disk such as MO, a semiconductor memory such as a USB memory, a memory card or the like), and installing the program in the general-purpose computer using the external storage device 6003. In addition, a means configured to supply a program to a computer is not limited to the case in which the program is supplied via the external storage device 6003. For example, the program may be supplied using a communication means such as the Internet, an exclusive line, or the like, without intervention of the external storage device 6003. In addition, the storage device 6001c or the external storage device 6003 is constituted by a computer-readable recording medium. Hereinafter, these are generally and simply referred to as a recording medium. In addition, when the term “recording medium” is used herein, the recording medium may include solely the storage device 6001c, solely the external storage device 6003, or both of these.

In addition, while the above-mentioned embodiment has been described as being divided into the center and the outer circumference of the wafer 200, the embodiment is not limited but the film thickness of the silicon-containing film may be controlled in more finely divided regions in the radial direction. For example, the regions may be divided into three regions of a center, an outer circumference, and a region between the center and the outer circumference of the substrate.

In addition, here, while the silicon nitride film has been exemplarily described as the hard mask film, the hard mask film is not limited thereto but, for example, may be a silicon carbide (SiC) film or a SiCN film.

In addition, when spatter processing or film-forming processing is performed, anisotropic processing or isotropic processing may be configured to be combined. According to the combination of the anisotropic processing or the isotropic processing, precise correction can be performed.

In addition, while the embodiment has been described using a 300 mm wafer, the embodiment is not limited thereto. For example, the embodiment is more effective when a large-scaled substrate such as a 450 mm wafer or the like is used. In the case of the large-scaled substrate, this is because influence of the polishing process (S103) becomes more remarkable. That is, a difference in film thickness between the poly-Si film 2005a and the poly-Si film 2005b is further increased. As the film thickness is corrected in the hard mask film forming process, deviation of the properties of the substrate can be suppressed even in the large-scaled substrate.

According to the present invention, deviation of properties of a semiconductor device can be suppressed.

### Preferred Embodiments of the Invention

Hereinafter, preferred embodiments according to the present invention are supplementarily noted.

### Supplementary Note 1

According to an aspect of the present invention, there is provided a substrate processing apparatus including: a receiving member configured to receive data representing a film thickness distribution of a silicon-containing film formed on a substrate; a substrate support where the substrate is placed; a gas supply member configured to supply gases in a manner that a hard mask film having a film thickness distribution different from that of the silicon-containing film is formed on the silicon-containing film to maintain a height of an upper surface of the hard mask film in a predetermined range.

### Supplementary Note 2

In the substrate processing apparatus of Supplementary Note 1, preferably, the gas supply member is further configured to supply the gases in a manner that an amount of exposure to a main component of a process gas per unit area of the substrate at a peripheral portion of a surface of the substrate is smaller than an amount of exposure to the main component of the process gas per unit area of the substrate at a center portion of the surface of the substrate when the data indicates a thickness of the silicon-containing film at the peripheral portion is greater than a thickness of the silicon-containing film at the center portion.

### Supplementary Note 3

In the substrate processing apparatus of Supplementary Note 2, preferably, the gas supply member is further configured to supply the gases in a manner that a temperature of the center portion is higher than a temperature of the peripheral portion when the data indicates the thickness of the silicon-containing film at the peripheral portion is greater than the thickness of the silicon-containing film at the center portion.

### Supplementary Note 4

In the substrate processing apparatus of Supplementary Note 3, preferably, the silicon-containing film includes polycrystalline silicon.

### Supplementary Note 5

In the substrate processing apparatus of Supplementary Note 1, preferably, the gas supply member is further configured to supply the gases in a manner that an amount of a process gas supplied to a peripheral portion of a surface of the substrate is smaller than an amount of the process gas supplied to a center portion of the surface of the substrate when the data indicates a thickness of the silicon-containing film at the peripheral portion is greater than a thickness of the silicon-containing film at the center portion.

### Supplementary Note 6

In the substrate processing apparatus of Supplementary Note 1, preferably, the substrate support is configured to adjust a temperature distribution of the substrate in a manner that a temperature of the center portion is higher than a temperature of the peripheral portion when the data indicates the thickness of the silicon-containing film at the peripheral portion is greater than the thickness of the silicon-containing film at the center portion.

### Supplementary Note 7

In the substrate processing apparatus of Supplementary Note 1, preferably, the gas supply member is further configured to supply the gases in a manner that a concentration of a main component of a process gas at a peripheral portion of a surface of the substrate is lower than a concentration of the main component of the process gas at a center portion of the surface of the substrate when the data indicates a thickness of the silicon-containing film at the peripheral portion is greater than a thickness of the silicon-containing film at the center portion.

### Supplementary Note 8

In the substrate processing apparatus of Supplementary Note 7, preferably, the gas supply member is further configured to adjust the concentration of the main component of the process gas by controlling an amount of an inert gas added to a process gas supplied to the peripheral portion to be greater than an amount of the inert gas added to the process gas supplied to the center portion.

### Supplementary Note 9

In the substrate processing apparatus of Supplementary Note 1, preferably, the substrate support is configured to adjust a temperature distribution of the substrate in a manner that a temperature of a center portion of a surface of the substrate is higher than a temperature of a peripheral portion of the surface of the substrate when the data indicates a thickness of the silicon-containing film at the peripheral portion is greater than a thickness of the silicon-containing film at the center portion.

### Supplementary Note 10

In the substrate processing apparatus of Supplementary Note 1, preferably, the gas supply member is further configured to supply the gases in a manner that an amount of exposure to a main component of a process gas per unit area of the substrate at a peripheral portion of a surface of the substrate is greater than an amount of exposure to the main component of the process gas per unit area of the substrate at a center portion of the surface of the substrate when the data indicates a thickness of the silicon-containing film at the peripheral portion is smaller than a thickness of the silicon-containing film at the center portion.

### Supplementary Note 11

In the substrate processing apparatus of Supplementary Note 10, preferably, the substrate support is configured to adjust a temperature distribution of the substrate in a manner that a temperature of the center portion is higher than a temperature of the peripheral portion when the data indicates the thickness of the silicon-containing film at the peripheral portion is smaller than the thickness of the silicon-containing film at the center portion.

### Supplementary Note 12

In the substrate processing apparatus of Supplementary Note 11, preferably, the silicon-containing film includes polycrystalline silicon.

### Supplementary Note 13

In the substrate processing apparatus of Supplementary Note 1, preferably, the gas supply member is further configured to supply the gases in a manner that an amount of a process gas supplied to a peripheral portion of a surface of the substrate is greater than an amount of the process gas supplied to a center portion of the surface of the substrate when the data indicates a thickness of the silicon-containing film at the peripheral portion is smaller than a thickness of the silicon-containing film at the center portion.

### Supplementary Note 14

In the substrate processing apparatus of Supplementary Note 13, preferably, the substrate support is configured to adjust a temperature distribution of the substrate in a manner that a temperature of the peripheral portion is higher than a temperature of the center portion when the data indicates the thickness of the silicon-containing film at the peripheral portion is smaller than the thickness of the silicon-containing film at the center portion.

### Supplementary Note 15

In the substrate processing apparatus of Supplementary Note 1, preferably, the gas supply member is further configured to supply the gases in a manner that a concentration of a main component of a process gas at a peripheral portion of a surface of the substrate is higher than a concentration of the main component of the process gas at a center portion of the surface of the substrate when the data indicates a thickness of the silicon-containing film at the peripheral portion is smaller than a thickness of the silicon-containing film at the center portion.

### Supplementary Note 16

In the substrate processing apparatus of Supplementary Note 15, preferably, the gas supply member is further configured to adjust the concentration of the main component of the process gas by controlling an amount of an inert gas added to a process gas supplied to the center portion to be greater than an amount of the inert gas added to the process gas supplied to the peripheral portion.

### Supplementary Note 17

In the substrate processing apparatus of Supplementary Note 1, preferably, the substrate support is configured to adjust a temperature distribution of the substrate in a manner that a temperature of a peripheral portion of a surface of the substrate is higher than a temperature of a center portion of the surface of the substrate when the data indicates a thickness of the silicon-containing film at the peripheral portion is smaller than a thickness of the silicon-containing film at the center portion.

### Supplementary Note 18

According to another aspect of the present invention, there is provided a substrate processing system including: a first device configured to form a silicon-containing film on a substrate; a second device configured to polish the silicon-containing film; a third device configured to obtain a film thickness distribution of a polished silicon-containing film by measuring a thickness of the polished silicon-containing film; and a fourth device configured to form a hard mask film having a film thickness distribution different from that of the polished silicon-containing film on the polished silicon-containing film to maintain a height of an upper surface of the hard mask film in a predetermined range.

### Supplementary Note 19

In the substrate processing system of Supplementary Note 18, preferably, a predetermined pattern is formed on the hard mask film.

### Supplementary Note 20

In the substrate processing system of Supplementary Note 19, further includes an exposure device configured to perform an exposure process to the substrate, and the fourth device is further configured to adjust the film thickness distribution of the hard mask film to maintain a distribution of a depth of focus of the substrate in a predetermined range when the substrate is processed by the exposure device.

### Supplementary Note 21

According to still another aspect of the present invention, there is provided a method of manufacturing a semiconductor device including: (a) forming a silicon-containing film on a substrate; (b) polishing the silicon-containing film; (c) obtaining a film thickness distribution of a polished silicon-containing film by measuring a thickness of the polished silicon-containing film; and (d) forming a hard mask layer having a film thickness distribution different from that of the polished silicon-containing film on the polished silicon-containing film.

### Supplementary Note 22

According to still another aspect of the present invention, there is provided a method of manufacturing a semiconductor device including: (a) receiving data representing a film thickness distribution of a polished silicon-containing film formed on a substrate; (b) placing the substrate on the substrate support; (c) forming a hard mask layer having a film thickness distribution different from that of the polished silicon-containing film on the polished silicon-containing film based on the data.

### Supplementary Note 23

According to still another aspect of the present invention, there is provided a program for causing a computer to control a substrate processing apparatus to perform: (a) receiving data representing a film thickness distribution of a polished silicon-containing film formed on a substrate; (b) placing the substrate on the substrate support; (c) forming a hard mask layer having a film thickness distribution different from that of the polished silicon-containing film on the polished silicon-containing film based on the data.

### Supplementary Note 24

According to still another aspect of the present invention, there is provided a non-transitory computer-readable recording medium storing a program for causing a computer to control a substrate processing apparatus to perform: (a) receiving data representing a film thickness distribution of a polished silicon-containing film formed on a substrate; (b) placing the substrate on the substrate support; (c) forming a hard mask layer having a film thickness distribution different from that of the polished silicon-containing film on the polished silicon-containing film based on the data.

### Supplementary Note 25

According to still another aspect of the present invention, there is provided a substrate processing apparatus including: a receiving member configured to receive data representing a film thickness distribution of a silicon-containing film formed on a substrate as a gate electrode layer; a substrate support where the substrate is placed; a gas supply member configured to supply gases in a manner that a hard mask film having a film thickness distribution different from that of the silicon-containing film is formed on the silicon-containing film to maintain a height of an upper surface of the hard mask film in a predetermined range.

### Supplementary Note 26

According to still another aspect of the present invention, there is provided a substrate processing apparatus including: a receiving member configured to receive data representing a film thickness distribution of a silicon-containing film formed on a substrate as a dummy gate electrode layer; a substrate support where the substrate is placed; a gas supply member configured to supply gases in a manner that a hard mask film having a film thickness distribution different from that of the silicon-containing film is formed on the silicon-containing film to maintain a height of an upper surface of the hard mask film in a predetermined range.

What is claimed is:

1. A method of manufacturing a semiconductor device, comprising:
(a) receiving data representing a first film thickness distribution of a polished silicon-containing film formed on a substrate;
(b) placing the substrate on a substrate support; and
(c) forming on the polished silicon-containing film a hard mask film having a second film thickness distribution different from first film thickness distribution based on the data received in (a).

2. The method of claim 1, wherein an amount of exposure to a main component of a process gas supplied in (c) to a peripheral portion of the substrate is smaller than an amount of exposure to the main component of the process gas supplied in (c) to a center portion of the substrate when the data received in (a) indicates the polished silicon-containing film at the peripheral portion is thicker than the polished silicon-containing film at the center portion, and
the amount of exposure to the main component of the process gas supplied in (c) to the peripheral portion of the substrate is greater than the amount of exposure to the main component of the process gas supplied in (c) to the center portion when the data received in (a) indicates the polished silicon-containing film at the center portion is thicker than the polished silicon-containing film at the peripheral portion.

3. The method of claim 2, wherein the center portion of the substrate is maintained at a temperature higher than a temperature of the peripheral portion of the substrate in (c) when the data received in (a) indicates the polished silicon-containing film at the peripheral portion is thicker than the polished silicon-containing film at the center portion, and
the peripheral portion of the substrate is maintained at a temperature higher than a temperature of the center portion of the substrate in (c) when the data received in (a) indicates the polished silicon-containing film at the center portion is thicker than the polished silicon-containing film at the peripheral portion.

4. The method of claim 1, wherein an amount of a process gas supplied in (c) to a peripheral portion of the substrate is smaller than an amount of the process gas supplied in (c) to a center portion of the substrate when the data received in (a) indicates the polished silicon-containing film at the peripheral portion is thicker than the polished silicon-containing film at the center portion, and
the amount of the process gas supplied in (c) to the peripheral portion of the substrate is greater than the amount of the process gas supplied in (c) to the center portion when the data received in (a) indicates the polished silicon-containing film at the center portion is thicker than the polished silicon-containing film at the peripheral portion.

5. The method of claim 1, wherein a concentration of a main component of a process gas supplied in (c) to a peripheral portion of the substrate is lower than a concentration of the main component of the process gas supplied in (c) to a center portion of the substrate when the data received in (a) indicates the polished silicon-containing film at the peripheral portion is thicker than the polished silicon-containing film at the center portion, and
the concentration of the main component of the process gas supplied in (c) to the peripheral portion of the substrate is higher than the concentration of the main component of the process gas supplied in (c) to the center portion when the data received in (a) indicates the polished silicon-containing film at the center portion is thicker than the polished silicon-containing film at the peripheral portion.

6. The method of claim 5, wherein an amount of an inert gas added to the process gas supplied in (c) to the peripheral portion is greater than an amount of the inert gas added to the process gas supplied in (c) to the center portion to control the concentrations of the main component to the peripheral portion and the center portion when the data received in (a) indicates the polished silicon-containing film at the peripheral portion is thicker than the polished silicon-containing film at the center portion, and
the amount of the inert gas added to the process gas supplied in (c) to the center portion is greater than the amount of the inert gas added to the process gas supplied in (c) to the peripheral portion to control the concentrations of the main component to the peripheral portion and the center portion when the data received in (a) indicates the polished silicon-containing film at the center portion is thicker than the polished silicon-containing film at the peripheral portion.

7. The method of claim 1, wherein a center portion of the substrate is maintained at a temperature higher than a temperature of a peripheral portion of the substrate in (c) when the data received in (a) indicates the polished silicon-containing film at the peripheral portion is thicker than the polished silicon-containing film at the center portion, and
the peripheral portion of the substrate is maintained at a temperature higher than a temperature of the center portion of the substrate in (c) when the data received in (a) indicates the polished silicon-containing film at the center portion is thicker than the polished silicon-containing film at the peripheral portion.
